(19) United States
(12) Patent Application Publication
(10) Pub. No.: US 2017/0069388 A1
(43) Pub. Date: Mar. 9, 2017

(54) NON-VOLATILE MEMORY DEVICE

(71) Applicant: Kabushiki Kaisha Toshiba, Minato-ku (JP)

(72) Inventors: Fumitaka ARAI, Yokkaichi (JP); Akio KANEKO, Yokkaichi (JP)

(73) Assignee: Kabushiki Kaisha Toshiba, Minato-ku (JP)

(21) Appl. No.: 15/068,084

(22) Filed: Mar. 11, 2016

Related U.S. Application Data
(60) Provisional application No. 62/214,025, filed on Sep. 3, 2015.

(51) Int. Cl. G11C 16/14; G11C 16/26; H01L 29/788; G11C 16/08; H01L 27/115; H01L 23/528

(52) U.S. Cl. CPC G11C 16/14; H01L 27/11524; H01L 23/528; H01L 29/7883; G11C 16/08; G11C 16/26

(57) ABSTRACT

A nonvolatile memory device includes a conductive layer, a semiconductor layer extending in a first direction on the conductive layer, a first insulating layer provided between the conductive layer and the semiconductor layer, a word line extending in a second direction on the semiconductor layer, the second direction intersecting the first direction, a charge storage layer provided between the semiconductor layer and the word line, and a circuit electrically connected to the conductive layer. The circuit applies an electric potential to the conductive layer when programming data, the electric potential of the conductive layer having the same polarity as an electric potential of the word line.

### CROSS-REFERENCE TO RELATED APPLICATIONS

This application is based upon and claims the benefit of priority from U.S. Provisional Patent Application 62/214,025 filed on Sep. 3, 2015; the entire contents of which are incorporated herein by reference.

### FIELD

Embodiments are generally related to a non-volatile memory device.

### BACKGROUND

A nonvolatile memory device such as a NAND type memory device comprises a memory cell transistor including a semiconductor layer, a charge storage layer, and a word line. The charge storage layer is provided, with an insulating layer interposed, between the semiconductor layer and the word line. When programming information to the memory cell transistor, electric charges are injected from the semiconductor layer into the charge storage layer by applying a prescribed bias between the semiconductor layer and the word line. On the other hand, when erasing the information stored in the memory cell transistor, the reverse bias opposite to the programming bias is applied between the semiconductor layer and the word line in order to remove the electric charges from the charge storage layer. However, such programming and erasing of the information damages the insulating layer between the semiconductor layer and the charge storage layer and causes the data retention characteristics to degrade. Also, the life of the semiconductor memory device is limited by the number of times of programming and erasing.

For example, one word line is shared by multiple memory cell transistors. The control circuit applies the bias via the word line not only to the memory cell transistor that is selected for programming the information but also to the memory cell transistors that are unselected. Thus, it is desirable for the NAND type memory device to have a structure capable of reducing the bias applied to the unselected memory cell transistors, thereby suppressing the damage of the insulating layer.

### BRIEF DESCRIPTION OF THE DRAWINGS

FIGS. 1A and 1B are schematic views showing a nonvolatile memory device according to a first embodiment;

FIGS. 2A, 2B, 2C and 2D are schematic cross-sectional views showing operations of the memory cell array according to the first embodiment;

FIGS. 3A, 3B, 3C and 3D are graphs showing characteristics of the nonvolatile memory device according to the first embodiment;

FIGS. 4A, 4B, 4C and 4D are schematic cross-sectional views showing operations of a memory cell array according to a variation of the first embodiment;

FIGS. 5A, 5B, 6A and 6B are schematic cross-sectional views showing operations of memory cell arrays according to other variations of the first embodiment;

FIG. 7 is a schematic view showing a nonvolatile memory device according to a second embodiment;

FIGS. 8A and 8B are schematic cross-sectional views showing operations of the memory cell array according to the second embodiment;

FIGS. 9A and 9B are schematic views showing a memory cell array according to a third embodiment;

FIGS. 10A, 10B, 11A, 11B, 11C, 12A, 12B, 13A, 13B, 13C, 13D, 13E, 14A, 14B, 14C, 14D, 15A, 15B, 15C, 15D, 15E, 16A, 16B, 16C, 16D, 16E, 17A, 17B, 17C, 17D, 17E, 18A, 18B, 18C, 18D, 18E, 19A, 19B, 19C, 19D, 19E, 20A, 20B, 20C, 20D, 20E, 21A, 21B, 21C, 21D, 21E, 22A, 22B, 22C, 22D and 22E are schematic cross-sectional views showing a manufacturing processes of the memory cell array according to the third embodiment;

FIGS. 23A, 23B, 23C, 23D and 23E are schematic views showing the memory cell array according to the third embodiment;

FIGS. 24A, 24B, 24C, 24D and 24E are schematic views showing a memory cell array according to a variation of the third embodiment;

FIGS. 25A, 25B, 25C, 25D and 25E are schematic views showing a memory cell array according to another variation of the third embodiment; and

FIGS. 26A, 26B, 26C and 26D are schematic views showing characteristics of the nonvolatile memory device according to the first embodiment.

### DETAILED DESCRIPTION

According to one embodiment, a nonvolatile memory device includes a conductive layer, a semiconductor layer extending in a first direction on the conductive layer, a first insulating layer provided between the conductive layer and the semiconductor layer, a word line extending in a second direction on the semiconductor layer, the second direction intersecting the first direction, a charge storage layer provided between the semiconductor layer and the word line, and a circuit electrically connected to the conductive layer. The circuit applies an electric potential to the conductive layer when programming data, the electric potential of the conductive layer having the same polarity as an electric potential of the word line.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

The embodiments described below are not limited to the examples described therein. Also, the components and the operations thereof described in each embodiment are not unique to each embodiment and are mutually applicable if technically feasible.

### First Embodiment

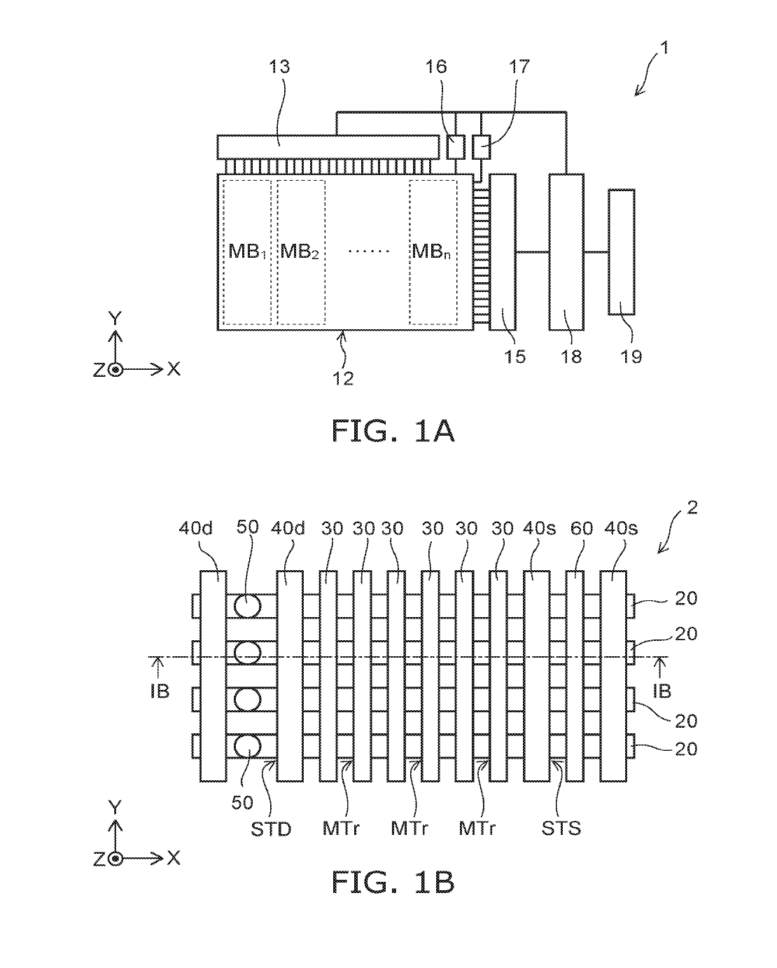

FIGS. 1A and 1B are schematic views showing a nonvolatile memory device 1 according to a first embodiment. FIG. 1A is a block diagram showing the configuration of the nonvolatile memory device 1. FIG. 1B is a schematic view showing a memory cell array 2 of the nonvolatile memory device 1.

The nonvolatile memory device 1 is, for example, a NAND EEPROM (electrically erasable programmable ROM). As shown in FIG. 1A, the nonvolatile memory device 1 includes, for example, a memory unit 12, a row decoder 13, a sense amplifier 15, a source potential supply unit 16, a substrate potential supply unit 17, a controller 18, and an interface 19. The row decoder 13, the sense amplifier 15, the source potential supply unit 16, the substrate potential supply unit 17, the controller 18, and the interface 19 each are functional blocks and are included in a so-called peripheral circuit. It is sufficient for the peripheral circuit to include the functions of the blocks as an entirety; and it is unnecessary to include the functions in a form in which the circuit region corresponding to each block can be discriminated.

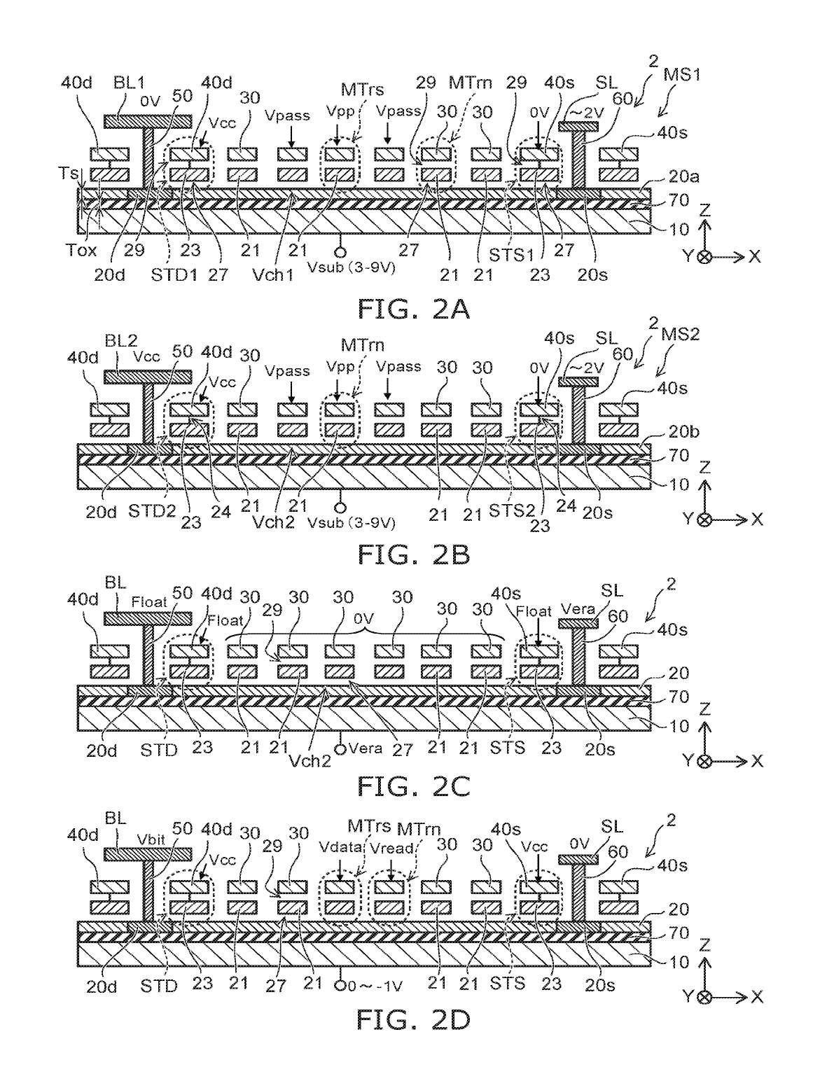

The memory unit 12 includes, for example, multiple memory blocks MB. Each of the memory blocks MB includes the memory cell array 2 shown in FIG. 2. The memory cell array 2 includes multiple semiconductor layers 20, word lines 30, and selection gates 40d and 40s. The semiconductor layers 20 extend in a first direction (hereinbelow, an X-direction). The semiconductor layers 20 are arranged in a second direction (hereinbelow, a Y-direction). The semiconductor layers 20 are provided to be parallel to each other.

The word lines 30 extend in a direction crossing the semiconductor layers 20. In the example, the word lines 30 extend in the Y-direction. The multiple word lines 30 are arranged in the X-direction. The word lines 30 are provided to be parallel to each other. Charge storage layers 21 (referring to FIG. 2A) are provided at the portions where the semiconductor layers 20 and the word lines 30 cross. Memory cell transistors MTr are provided at the portions where the semiconductor layers 20 and the word lines 30 cross. The memory cell transistors MTr include the charge storage layers 21 provided between the semiconductor layers 20 and the word lines 30. Also, the multiple memory cell transistors MTr share one word line 30.

The selection gates 40d and 40s extend in directions crossing the semiconductor layers 20. In the example, the selection gates 40d and 40s extend in the Y-direction. The multiple word lines 30 10 are arranged between the selection gate 40d and the selection gate 40s. Selection transistors STD are provided at the portions where the semiconductor layers 20 and the selection gate 40d cross. Selection transistors STS are provided at the portions where the semiconductor layers 20 and the selection gate 40s cross. Multiple 15 selection transistors STD share one selection gate 40d. Multiple selection transistors STS share one selection gate 40s.

Multiple drain contacts 50 are provided on the side of the selection gate 40d opposite to the word lines 30. The drain contacts 50 are electrically connected respectively to the semiconductor layers 20. The drain contacts 50 are electrically connected to bit lines BL (referring to FIG. 2A). In other words, the drain contacts 50 electrically connect the semiconductor layers 20 to the bit lines BL.

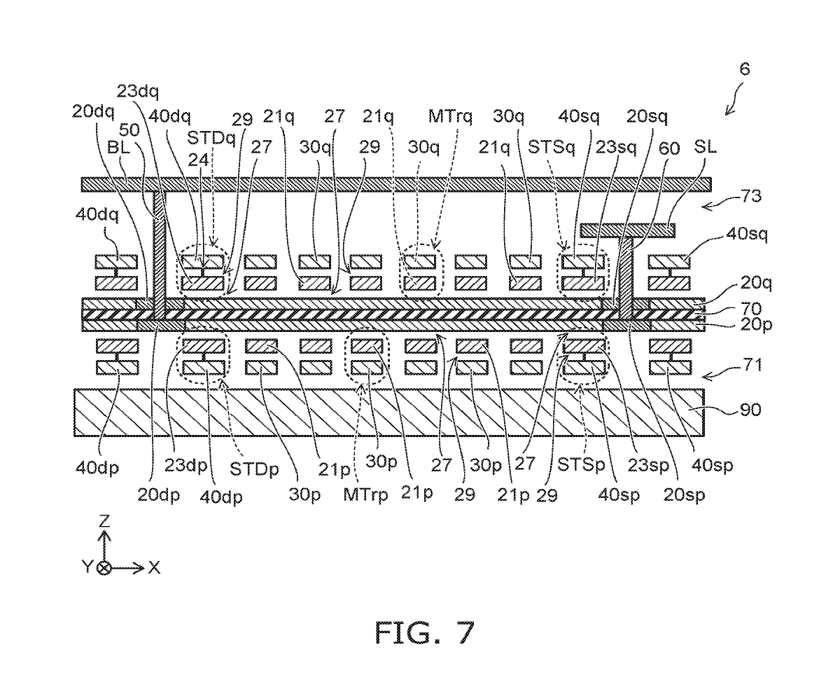

A source contact 60 is provided on the side of the selection gate 40s opposite to the word lines 30. For example, the source contact 60 extends in the Y-direction and is electrically connected to the multiple semiconductor layers 20. The source contact 60 is shared by the multiple semiconductor layers 20. The source contact 60 electrically connects the semiconductor layers 20 to a not-shown source line SL (referring to FIG. 7).

The row decoder 13 supplies a gate potential V_{GM} to the multiple memory cell transistors MTr via the word lines 30. The row decoder 13 supplies a gate potential V_{GD} to the multiple selection transistors STD via the selection gate 40d. Also, the row decoder 13 supplies a gate potential V_{GS} to the multiple selection transistors STS via the selection gate 40s.

The sense amplifier 15 is electrically connected to the semiconductor layers 20 via the bit lines BL and the drain contacts 50. The source potential supply unit 16 is electrically connected to the semiconductor layers 20 via the source line SL and the source contact 60. The substrate potential supply unit 17 is electrically connected to a not-shown substrate 10 (referring to FIG. 2A). The sense amplifier 15 and the source potential supply unit 16 maintain the semiconductor layers 20 at a prescribed potential. Namely, the sense amplifier 15 and the source potential supply unit 16 supply a channel potential Vch to the memory cell transistors MTr.

For example, the controller 18 receives a command sent from the outside via the interface 19 and performs the programming of data, the reading of data, and the erasing of data to and from the memory cell transistors MTr. Specifically, the controller 18 performs the programming of the data, the reading of the data, and the erasing of the data by controlling the gate potential V_{GM} and the channel potential Vch of the memory cell transistors MTr via the row decoder 13, the sense amplifier 15, the source potential supply unit 16, and the substrate potential supply unit 17.

FIGS. 2A to 2D are schematic cross-sectional views showing operations of the memory cell array 2. FIGS. 2A to 2D are cross-sectional views along line 1B-1B shown in FIG. 1B. In FIGS. 2A to 2D, the insulating layers that are provided to be higher than the semiconductor layer 20 are not shown.

As shown in FIGS. 2A to 2D, the memory cell array 2 is provided on the substrate 10. The memory cell array 2 further includes an insulating layer 70 between the substrate 10 and the semiconductor layer 20. The insulating layer 70 electrically insulates the semiconductor layer 20 from the substrate 10. The word lines 30 and the selection gates 40d and 40s are provided above the semiconductor layer 20.

The substrate 10 is, for example, a silicon substrate. The insulating layer 70 is, for example, a silicon oxide layer. The semiconductor layer 20 is, for example, a silicon layer. For example, the nonvolatile memory device 1 is made using a wafer having an SOI (Silicon on Insulator) structure.

The memory cell transistor MTr includes a portion of the semiconductor layer 20, the charge storage layer 21, and a portion of the word line 30. The charge storage layer 21 is provided between the semiconductor layer 20 and the word line 30. The portion of the semiconductor layer 20 functions as a channel of the memory cell transistor MTr; and the portion of the word line 30 functions as a control gate of the memory cell transistor MTr. The memory cell transistor MTr further includes an insulating layer 27 and an insulating layer 29. The insulating layer 27 is provided between the semiconductor layer 20 and the charge storage layer 21; and the insulating layer 29 is provided between the charge storage layer 21 and the word line 30. For example, the insulating layer 27 functions as a tunneling insulating layer. For example, the insulating layer 29 functions as a blocking insulating layer.

The selection transistor STD includes a portion of the semiconductor layer 20, a conductive layer 23, and a portion of the selection gate 40d. The conductive layer 23 is provided between the semiconductor layer 20 and the selection gate 40d. The conductive layer 23 includes, for example, the same material as the charge storage layer 21. The selection transistor STD further includes the insulating layer 27 and the insulating layer 29. The insulating layer 27 is provided between the semiconductor layer 20 and the conductive layer 23; and the insulating layer 29 is provided between the conductive layer 23 and the selection gate 40d. The conductive layer 23 is electrically connected to the selection gate 40d via a connecting portion 24 extending through the insulating layer 29. The portion of the semiconductor layer 20 functions as a channel of the selection transistor STD; and the conductive layer 23 and the portion of the selection gate 40d function as a gate electrode of the selection transistor STD. The insulating layer 27 functions as a gate insulation layer of the selection transistor STD.

The conductive layers 23 are not necessarily electrically connected to the selection gates 40d and 40s. For example, the conductive layers 23 may be electrically isolated from the selection gates 40d and 40s if the threshold voltages of the selection transistors STD and STS are in a prescribed range. Thereby, the process of forming the connecting portions 24 can be omitted.

The selection transistor STS includes a portion of the semiconductor layer 20, the conductive layer 23, and a portion of the selection gate 40s. The conductive layer 23 is provided between the semiconductor layer 20 and the selection gate 40s. The selection transistor STS further includes the insulating layer 27 and the insulating layer 29. The insulating layer 27 is provided between the semiconductor layer 20 and the conductive layer 23; and the insulating layer 29 is provided between the conductive layer 23 and the selection gate 40s. The conductive layer 23 is electrically connected to the selection gate 40s via a connecting portion extending through the insulating layer 29. The portion of the semiconductor layer 20 functions as a channel of the selection transistor STS; and the conductive layer 23 and the portion of the selection gate 40s function as a gate electrode of the selection transistor STS. The insulating layer 27 functions as a gate insulation layer of the selection transistor STS.

The semiconductor layer 20 includes a contact portion 20d and a contact portion 20s. The drain contact 50 is electrically connected to the contact portion 20d. The source contact 60 is electrically connected to the contact portion 20s. The contact portions 20d and 20s are, for example, regions of the semiconductor layer 20 doped with an n-type impurity having a high concentration.

The memory cell array 2 includes, for example, multiple memory strings. One memory string includes, between the drain contact 50 and the source contact 60, the multiple memory cell transistors MTr and the selection transistors STD and STS that share one semiconductor layer 20. The drain contact 50 is provided on the drain side of the selection transistor STD; and the memory cell transistors MTr are provided on the source side of the selection transistor STD. Also, the memory cell transistors MTr are provided on the drain side of the selection transistor STS; and the source contact 60 is provided on the source side of the selection transistor STS.

The semiconductor layer 20 is electrically connected to the bit line BL via the drain contact 50. The bit line BL extends in the X-direction above the word lines 30 and the selection gates 40d and 40s (referring to FIG. 7). The bit line BL is electrically connected to the sense amplifier 15. Also, the semiconductor layer 20 is electrically connected to the source line SL via the source contact 60. The source line SL is electrically connected to the source potential supply unit 16.

FIGS. 2A and 2B show the gate potentials V_{GM}, V_{GD}, and V_{GS}, the potential of the bit line BL, and the potential of the source line SL when programming data. FIG. 2A shows a memory string MS1; and FIG. 2B shows a memory string MS2. The memory string MS1 includes a memory cell transistor MTrs that is selected for programming data, and memory cell transistors MTrn that are unselected. The memory string MS2 includes only the unselected memory cell transistors MTrn. The word lines 30 and the selection gates 40d and 40s are shared by the memory strings MS1 and MS2.

In the description hereinbelow, the selected memory cell transistor MTrs and the unselected memory cell transistors MTrn may be discriminated; or the two may be generally referred to as the memory cell transistor MTr. The other components also may be discriminated individually or may be generally referred to.

For example, via the sense amplifier 15, the controller 18 selects a bit line BL1 electrically connected to the memory string MS1 and sets the potential of the bit line BL1 to 0 (zero) V. On the other hand, via the sense amplifier 15, the controller 18 applies Vcc to a bit line BL2 connected to the memory string MS2. For example, a potential of 2 V is applied to the source line SL via the source potential supply unit 16.

Then, via the row decoder 13, the controller 18 applies Vcc to the selection gate 40d and sets the potential of the selection gate 40s to 0 (zero) V. Further, via the row decoder 13, the controller 18 applies Vpp to the word line 30 connected to the memory cell transistor MTrs. Also, via the row decoder 13, the controller 18 applies Vpass to the other word lines 30 connected to the memory cell transistors MTrn. Here, Vcc is the power supply voltage and is, for example, 3 V. Vpp is the programming voltage and is, for example, 20 V. Vpass is higher than the threshold voltage of the memory cell transistors MTrn and switches the memory cell transistors MTrn ON. Vpass is, for example, 9 V.

In the memory string MS1 shown in FIG. 2A, the gate potential V_{GD} of a selection transistor STD1 is Vcc; and the drain potential of the selection transistor STD1 is 0 V. Accordingly, the selection transistor STD1 is switched to the ON state. On the other hand, the gate potential V_{GS} of a selection transistor STS1 is 0 V; and the source potential of the selection transistor STS1 is 2 V. Therefore, the selection transistor STS1 is switched to the OFF state. Also, the gate potentials of the memory cell transistors MTrs and MTrn are higher than the threshold voltage; and the memory cell transistors MTrs and MTrn are switched to the ON state. As a result, a channel potential Vch1 of the memory cell transistors MTr is 0 V which is the same as that of the bit line BL1. Then, by the programming voltage Vpp applied to the gate-channel of the memory cell transistor MTrs, charge is injected from a semiconductor layer 20a into the charge storage layer 21; and the data is programmed to the memory cell transistor MTrs.

In contrast, in the memory string MS2 shown in FIG. 2B, Vcc is applied to the drain side of a selection transistor STD2 via the bit line BL2. The selection transistor STD2 shares the selection gate 40d with the selection transistor STD1. Accordingly, the gate potential V_{GD} is Vcc. Therefore, the selection transistor STD2 is switched to the OFF state. On the other hand, a selection transistor STS2 shares the selection gate 40s with the selection transistor STS1; and the gate potential V_{GS} of the selection transistor STS2 is 0 V. A potential of 2 V is applied to the source side of the selection transistor STS2 via the source line SL. Therefore, the selection transistor STS2 is switched to the OFF state. As a result, a channel potential Vch2 of the memory cell transistors MTr is a floating potential.

The channel potential Vch2 of the memory string MS2 is dependent on the potentials of the word line 30 and the substrate 10 via a capacitive coupling between a semiconductor layer 20b and the word line 30 and a capacitive coupling between the substrate 10 and the semiconductor layer 20. In the embodiment, for example, the controller 18 applies a bias Vsub to the substrate 10 via the substrate potential supply unit 17. Vsub is, for example, 3 to 9 V. Accordingly, the channel potential Vch2 is pushed upward to the positive side. As a result, in the memory string MS2, it is possible to set the potential difference between the word line 30 and the channel of the memory cell transistor MTrn to be small; and, for example, the damage of the tunneling insulating layer may be suppressed.

For example, when programming data, the programming voltage Vpp is applied to the control gates of the unselected memory cell transistors MTrn that share the word line 30 with the selected memory cell transistor MTrs. In contrast, by increasing the potential of the substrate 10 and increasing the channel potential Vch2 of the unselected memory cell transistors MTrn, the potential difference between the word line 30 and the channel thereof can be set to be smaller than Vpp. In other words, by boosting the channel potential, the damage of the tunneling insulating layer of the unselected memory cell transistors MTrn may be suppressed. As a result, the data retention characteristics of the memory cell transistors MTr are improved; and it is possible to realize a longer life of the nonvolatile memory device 1.

FIG. 2C shows the gate potentials V_{GM}, V_{GD}, and V_{GS}, the potential of the bit line BL, and the potential of the source line SL when erasing data. For example, the data erasure is executed collectively for each memory block MB.

As shown in FIG. 2C, the controller 18 applies an erasing voltage Vera via the source potential supply unit 16 to the source lines SL of the memory block MB for which the data is to be erased. On the other hand, the controller 18 sets the potential of the bit line BL to the floating potential via the sense amplifier 15. Also, via the row decoder, the controller 18 sets the potentials of the selection gates 40d and 40s to the floating potential and sets the potential of each word line 30 to 0 V.

By the potential setting recited above, the gate potential V_{GD} of the selection transistor STD is set to the floating potential; and the selection transistor STD is switched to the OFF state. Also, the gate potential V_{GS} of the selection transistor STS is set to the floating potential; and the source potential is Vera. Therefore, the selection transistor STS is switched to the ON state; and the channel potential Vch of the memory cell transistors MTr is set to Vera. As a result, Vera is applied between the word line 30 and the channel of the memory cell transistor MTr; and the electric charges are removed from the charge storage layer 21 into the semiconductor layer 20. Thereby, the data that is stored in the memory cell transistors MTr is erased.

When erasing data, it is favorable for the controller 18 to apply the potential of Vera to the substrate 10 via the substrate potential supply unit. Thereby, the substrate 10 and the semiconductor layer 20 are set to the same potential; and the damage of the insulating layer 70 occurring due to the electric field can be avoided.

FIG. 2D shows the gate potentials V_{GM}, V_{GD}, and V_{GS}, the potential of the bit line BL, and the potential of the source line SL when reading data. FIG. 2D is a cross-sectional view of a memory string MS including the memory cell transistor MTrs that is selected for reading the data.

As shown in FIG. 2D, the controller 18 applies Vcc to the selection gates 40d and 40s via the row decoder 13. Also, via the row decoder 13, the controller 18 applies Vdata to the word line 30 connected to the selected memory cell transistor MTrs and applies Vread to the word lines 30 connected to the unselected memory cell transistors MTrn. Then, the controller 18 applies Vbit to the bit line BL via the sense amplifier 15 and sets the potential of the source line SL to 0 V via the source potential supply unit 16. Here, Vread is a voltage that is higher than the threshold of the memory cell transistors MTr; and Vbit is, for example, a voltage that is between 0 V and Vcc.

By the potential setting recited above, the gate potentials V_{GD} and V_{GS} of the selection transistors STD and STS are set to Vcc; and the selection transistors STD and STS are switched to the ON state. Also, the gate potential V_{GM} of the unselected memory cell transistors MTrn is Vread; and the unselected memory cell transistors MTrn are switched to the ON state. Then, via the row decoder 13, the controller 18 sweeps Vdata and uses the sense amplifier 15 to sense the flow/non-flow of a channel current flowing through the semiconductor layer 20 from the bit line BL to the source line SL. The sweep range of Vdata includes the threshold voltage of the memory cell transistors MTr. In other words, the threshold voltage is sensed by sweeping the gate potential V_{GM} of the memory cell transistor MTrs. Thereby, the controller 18 can read the data stored in the memory cell transistor MTrs.

When reading the data, for example, it is favorable for the controller 18 to apply a potential of −1 V to 0 V to the substrate 10 via the substrate potential supply unit 17. Thereby, the channel resistance of the memory cell transistors MTr is reduced; and the current can be increased while reading. In other words, the Signal to Noise ratio of the channel current is set to be large when sensing; and the read-out precision of the data may be increased.

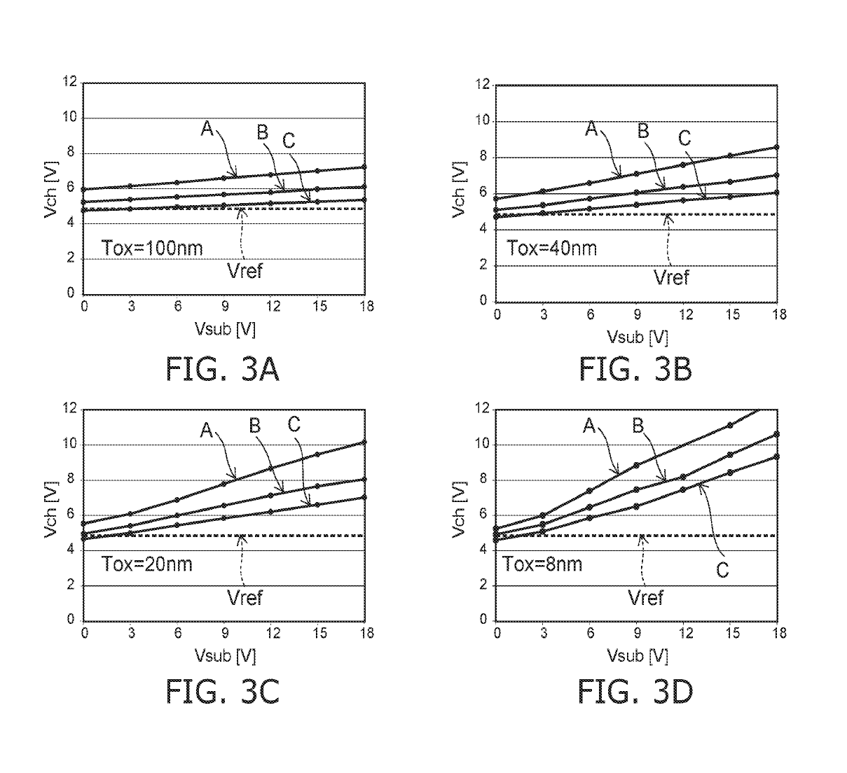

FIGS. 3A to 3D are graphs showing characteristics of the nonvolatile memory device 1 according to the first embodiment. FIGS. 3A to 3D are graphs showing the potential Vsub of the substrate 10 and the potential V_{Ch} of the channel in the floating state. FIG. 3A is the characteristics when a thickness T_{OX} in the Z-direction of the insulating layer 70 (referring to FIG. 2A) is set to 100 nm. FIG. 3B, T_{OX} is set to 40 nm; in FIG. 3C, T_{OX} is set to 20 nm; and in FIG. 3D, T_{OX} is set to 8 nm. Also, A shown in each figure illustrates the characteristic in the case where a thickness T_{S} in the Z-direction of the semiconductor layer 20 (referring to FIG. 2A) is set to 10 nm; B illustrates the characteristic in the case where the thickness T_{S} of the semiconductor layer 20 is set to 20 nm; and C illustrates the characteristic in the case where the thickness T_{S} of the semiconductor layer 20 is set to 30 nm.

As shown in FIGS. 3A to 3D, the channel potential Vch increases as the substrate potential Vsub is increased. Also, the channel potential Vch increases as the thickness T_{S} of the semiconductor layer 20 is reduced. In other words, the boost of the channel potential Vch can be increased as the thickness T_{S} of the semiconductor layer 20 is reduced. The increase amount of the channel potential Vch increases as the thickness T_{OX} of the insulating layer 70 is reduced. In other words, the boost of the channel potential Vch can be increased as the thickness T_{OX} of the insulating layer 70 is reduced.

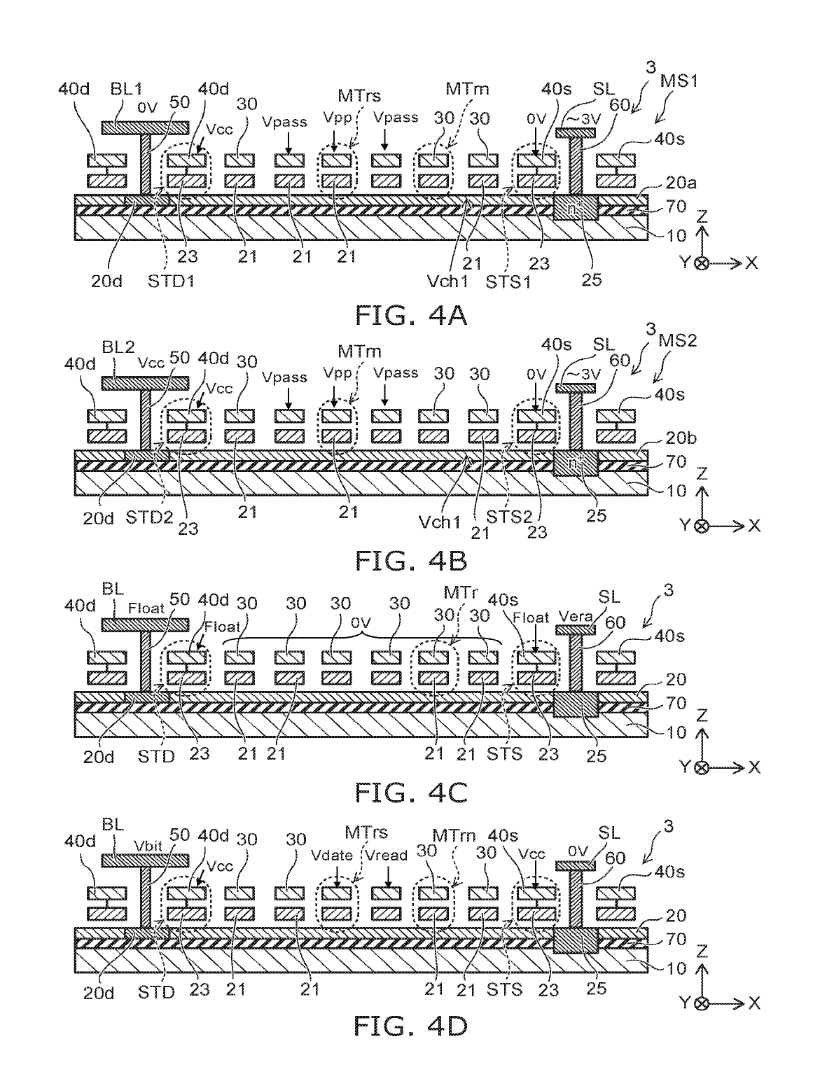

FIGS. 4A to 4D are schematic cross-sectional views showing operations of a memory cell array 3 according to a variation of the first embodiment. FIGS. 4A to 4D are cross-sectional views along line 1B-1B shown in FIG. 1B. In FIGS. 4A to 4D, the insulating layers that are provided to be higher than the semiconductor layer 20 are not shown.

As shown in FIGS. 4A to 4D, the memory cell array 3 is provided on the substrate 10. The memory cell array 3 includes the memory cell transistors MTr, the selection transistor STD, and the selection transistor STS. The memory cell array 3 further includes the insulating layer 70 between the substrate 10 and the semiconductor layer 20.

The memory cell array 3 includes a contact portion 25 on the source side of the selection transistor STS. The contact portion 25 is provided from the upper surface of the semiconductor layer 20 to a depth that reaches the substrate 10. The source contact 60 is electrically connected to the contact portion 25. The contact portion 25 is, for example, a semiconductor region doped with an n-type impurity having a high concentration and electrically connects the semiconductor layer 20 to the substrate 10.

FIGS. 4A and 4B show the gate potentials V_{GM}, V_{GD}, and V_{GS}, the potential of the bit line BL, and the potential of the source line SL when programming data. FIG. 4A shows the memory string MS1; and FIG. 4B shows the memory string MS2. The memory string MS1 includes the memory cell transistor MTrs that is selected for programming data, and the memory cell transistors MTrn that are unselected. The memory string MS2 includes only the unselected memory cell transistors MTrn. The word lines 30 and the selection gates 40d and 40s are shared by the memory strings MS1 and MS2.

For example, via the sense amplifier 15, the controller 18 selects the bit line BL1 electrically connected to the memory string MS1 and sets the potential of the bit line BL1 to 0 (zero) V. Also, via the sense amplifier 15, the controller 18 applies Vcc to the bit line BL2 connected to the memory string MS2. Further, for example, a potential of 3 V is applied to the source line SL via the source potential supply unit 16. In the example, the source line SL is electrically connected to the substrate 10 via the contact portion 25 and the source contact 60. Accordingly, a source potential of 3 V is applied also to the substrate 10.

Then, via the row decoder 13, the controller 18 applies Vcc to the selection gate 40d and sets the potential of the selection gate 40s to 0 (zero) V. Further, via the row decoder 13, the controller 18 applies Vpp to the word line 30 connected to the memory cell transistor MTrs. Also, via the row decoder 13, the controller 18 applies Vpass to the other word lines 30 connected to the memory cell transistors MTrn.

In the memory string MS1, the gate potential V_{GD} of the selection transistor STD1 is Vcc; and the potential on the drain side is 0 V. Accordingly, the selection transistor STD1 is switched to the ON state. On the other hand, the gate potential V_{GS} of the selection transistor STS1 is 0 V; and the source potential of the selection transistor STS1 is 3 V. Accordingly, the selection transistor STS1 is switched to the OFF state. The gate potentials of the memory cell transistors MTrs and MTrn are higher than the threshold voltage; and the memory cell transistors MTrs and MTrn are switched to the ON state. As a result, the channel potential Vch1 of the memory cell transistors MTr is 0 V which is the same as that of the bit line BL1. Then, by the programming voltage Vpp applied between the word line 30 and the channel of the memory cell transistor MTrs, electric charges are injected from the semiconductor layer 20a into the charge storage layer 21; and the data is programmed to the memory cell transistor MTrs.

In contrast, in the memory string MS2, Vcc is applied to the drain of the selection transistor STD2 via the bit line BL2. The selection transistor STD2 shares the selection gate 40d with the selection transistor STD1. Accordingly, the gate potential V_{GD} is Vcc. Therefore, the selection transistor STD2 is switched to the OFF state. On the other hand, the selection transistor STS2 shares the selection gate 40s with the selection transistor STS1; and the gate potential V_{GD} of the selection transistor STS2 is 0 V. A potential of 3 V is applied to the source of the selection transistor STS2 via the source line SL. Accordingly, the selection transistor STS2 is switched to the OFF state. As a result, the channel potential Vch2 of the memory cell transistors MTr is the floating potential.

A potential of 3 V is applied to the substrate 10 via the source line SL; and the substrate potential becomes 3 V. Accordingly, the channel potential Vch2 is pushed upward to the positive side. As a result, in the memory string MS2, the potential difference between the word line 30 and the channel of the memory cell transistor MTrn becomes small; and the damage of the tunneling insulating layer may be suppressed. Because the source potential supply unit 16 supplies the potential to the substrate 10, it is no longer necessary in this example to provide the substrate potential supply unit 17 in the peripheral circuit.

FIG. 4C shows the gate potentials V_{GM}, V_{GD}, and V_{GS}, the potential of the bit line BL, and the potential of the source line SL when erasing data. The controller 18 applies the erasing voltage Vera to the source line SL via the source potential supply unit 16. On the other hand, via the sense amplifier 15, the controller 18 sets the potential of the bit line BL to the floating potential. Also, via the row decoder, the controller 18 sets the potentials of the selection gates 40d and 40s to the floating potential and sets the potential of each word line 30 to 0 V.

By the potential setting recited above, the gate potential V_{GD} of the selection transistor STD is set to the floating potential; and the selection transistor STD is switched to the OFF state. Also, the gate potential V_{GS} of the selection transistor STS is set to the floating potential; and the source potential of the selection transistor STS is Vera. Therefore, the selection transistor STS is switched to the ON state; and the channel potential Vch of the memory cell transistors MTr is Vera. As a result, Vera is applied between the word line 30 and the channel of the memory cell transistor MTr; and the electric charges are removed from the charge storage layer 21 into the semiconductor layer 20. Thereby, the data that is stored in the memory cell transistors MTr is erased.

Vera is applied to the substrate 10 via the contact portion 25. Accordingly, the substrate 10 has the same potential as the semiconductor layer 20 when erasing data; and the damage of the insulating layer 70 due to the electric field is avoided.

FIG. 4D shows the gate potentials V_{GM}, V_{GD}, and V_{GS}, the potential of the bit line BL, and the potential of the source line SL when reading data. FIG. 4D is a cross-sectional view of the memory string MS including the memory cell transistor MTrs that is selected for reading the data.

As shown in FIG. 4D, the controller 18 applies Vcc to the selection gates 40d and 40s via the row decoder 13. Also, via the row decoder 13, the controller 18 applies Vdata to the word line 30 connected to the selected memory cell transistor MTrs and applies Vread to the word lines connected to the unselected memory cell transistors MTrn. Then, the controller 18 applies Vbit to the bit line BL via the sense amplifier 15 and sets the potential of the source line SL to 0 V via the source potential supply unit 16. The substrate 10 has the same potential as the source line SL.

By the potential setting recited above, the selection transistors STD and STS are switched to the ON state. The gate potential V_{GM} of the unselected memory cell transistors MTrn is Vread; and the unselected memory cell transistors MTrn are switched to the ON state. Then, the controller 18 sweeps Vdata via the row decoder 13 and senses the threshold voltage of the memory cell transistor MTrs.

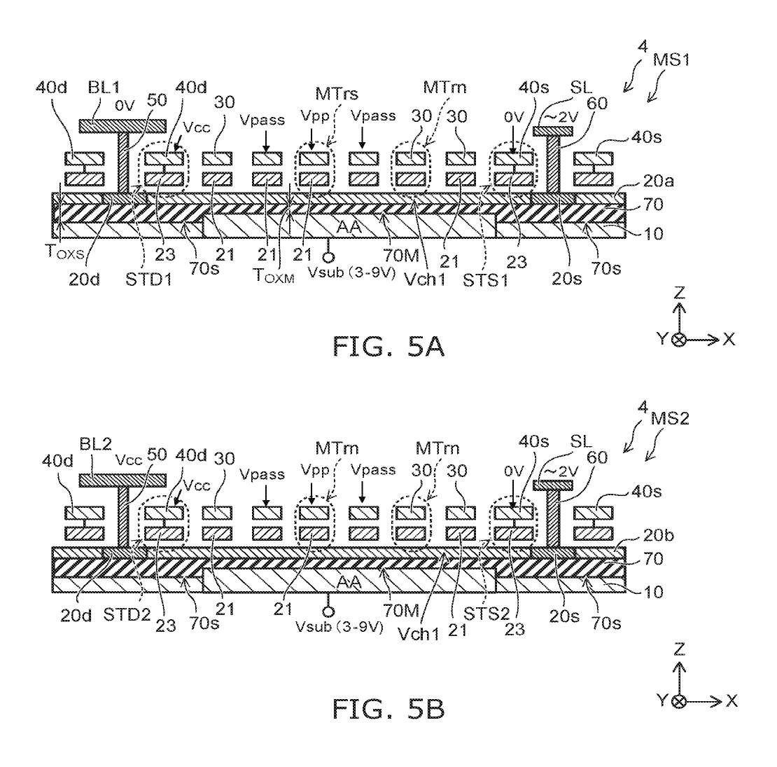

FIGS. 5A and 5B are schematic cross-sectional views showing operations of a memory cell array 4 according to a variation of the first embodiment. FIGS. 5A and 5B are cross-sectional views along line 1B-1B shown in FIG. 1B. In FIGS. 5A and 5B, the insulating layers that are provided to be higher than the semiconductor layers 20 are not shown.

As shown in FIGS. 5A and 5B, the memory cell array 4 is provided on the substrate 10. The memory cell array 4 includes the memory cell transistors MTr, the selection transistor STD, and the selection transistor STS. The memory cell array 4 further includes the insulating layer 70 between the substrate 10 and the semiconductor layer 20. The insulating layer 70 includes a first portion 70M and a second portion 70S. The first portion 70M is positioned under the memory cell transistors MTr. The second portion 70S is positioned under the selection transistor STD or STS. A thickness T_{OXS} in the Z-direction of the second portion 70S is thicker than a thickness T_{OXM} in the Z-direction of the first portion 70M.

FIGS. 5A and 5B show the gate potentials V_{GM}, V_{GD}, and V_{GS}, the potential of the bit line BL, and the potential of the source line SL when programming data. FIG. 5A shows the memory string MS1; and FIG. 5B shows the memory string MS2. The memory string MS1 includes the memory cell transistor MTrs that is selected for programming data, and the memory cell transistors MTrn that are unselected. The memory string MS2 includes only the unselected memory cell transistors MTrn. The word lines 30 and the selection gates 40d and 40s are shared by the memory strings MS1 and MS2.

For example, via the sense amplifier 15, the controller 18 selects the bit line BL1 electrically connected to the memory string MS1 and sets the potential of the bit line BL1 to 0 (zero) V. Also, via the sense amplifier 15, the controller 18 applies Vcc to the bit line BL2 connected to the memory string MS2. Further, for example, a potential of 2 V is applied to the source line SL via the source potential supply unit 16.

Then, via the row decoder 13, the controller 18 applies Vcc to the selection gate 40d and sets the potential of the selection gate 40s to 0 (zero) V. Further, via the row decoder 13, the controller 18 applies Vpp to the word line 30 connected to the memory cell transistor MTrs. Also, via the row decoder 13, the controller 18 applies Vpass to the other word lines 30 connected to the memory cell transistors MTrn.

In the memory string MS1, the selection transistor STD1 is switched to the ON state. On the other hand, the selection transistor STS1 is switched to the OFF state. The memory cell transistors MTrs and MTrn are switched to the ON state. As a result, the channel potential Vch1 of the memory cell transistors MTr is 0 V which is the same as the bit line BL1. Then, by the programming voltage Vpp applied between the gate-channel for the memory cell transistor MTrs, electric charges are injected from the semiconductor layer 20a into the charge storage layer 21; and the data is programmed to the memory cell transistor MTrs.

In contrast, in the memory string MS2, the selection transistors STD2 and STS2 are switched to the OFF state. Thus, the channel potential Vch2 of the memory cell transistors MTr is the floating potential.

The controller 18 applies the potential Vsub to the substrate 10 via the substrate potential supply unit 17. Vsub is, for example, 3 V to 9 V. Therefore, the channel potential Vch2 is pushed upward to the positive side. As a result, in the memory string MS2, the potential difference between the word line 30 and the channel of the memory cell transistor MTrn becomes small; and the damage of the tunneling insulating layer may be suppressed.

In the example, the insulating layer 70 includes the first portion 70M and the second portion 705. The thickness T_{OXS} of the second portion 70S is thicker than the thickness T_{OXM} of the first portion 70M. Accordingly, in the memory string MS2, the unintentional change of the potential between the selection gate 40 and the channel of the selection transistor STD or STS may be suppressed while maintaining the increase of the channel potential Vch of the memory cell transistors MTr. In other words, the operations of the selection transistors STD and STS may be stabilized.

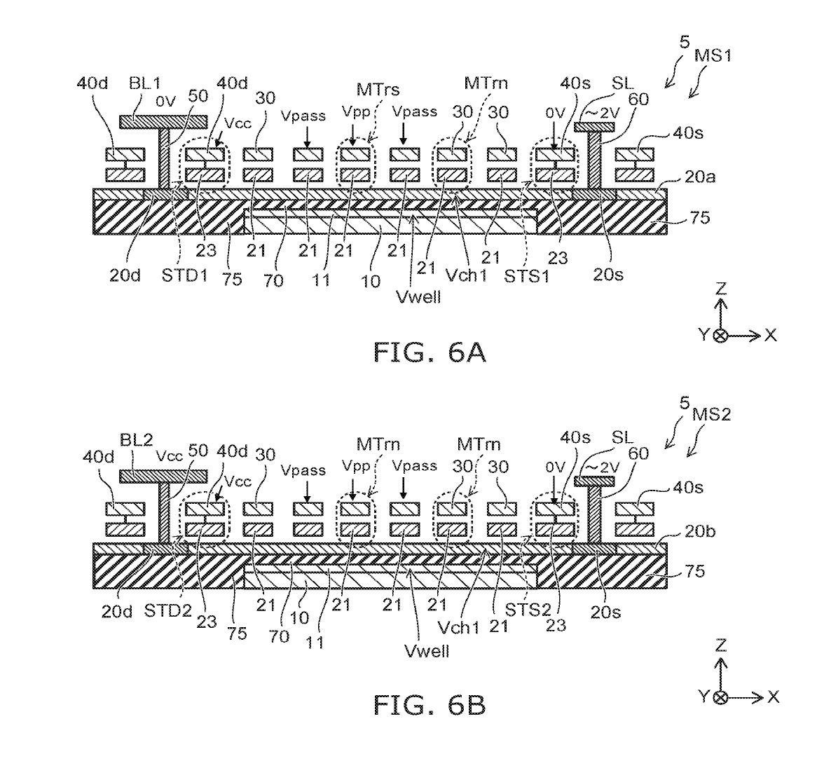

FIGS. 6A and 6B are schematic cross-sectional views showing operations of a memory cell array 5 according to a variation of the first embodiment. FIGS. 6A and 6B are cross-sectional views along line 1B-1B shown in FIG. 1B. In FIGS. 6A and 6B, the insulating layers that are provided to be higher than the semiconductor layers 20 are not shown.

The memory cell array 5 includes the memory cell transistors MTr and the selection transistors STD and STS provided on the semiconductor layer 20. Further, the memory cell array 5 includes, for example, a p-type well 11 provided in a top surface of the substrate 10. Also, the memory cell array includes the insulating layer 70 and STI (Shallow Trench Isolation) 75. The insulating layer 70 is provided between the p-type well 11 and the semiconductor layer 20. The memory cell transistors MTr are arranged on the p-type well 11 with the insulating layer 70 interposed between the p-type well 11 and the memory cell transistors MTr. The selection transistors STD and STS are provided on the STI 75. For example, the STI 75 is provided around the p-type well 11. In other words, the STI 75 defines the outer edge of the p-type well 11 and electrically insulates the p-type well 11 from the other portions of the substrate 10. For example, the p-type well 11 is provided for each memory block MB.

FIGS. 6A and 6B show the gate potentials V_{GM}, V_{GD}, and V_{GS}, the potential of the bit line BL, and the potential of the source line SL when programming data. FIG. 6A shows the memory string MS1; and FIG. 6B shows the memory string MS2. The memory string MS1 includes the memory cell transistor MTrs that is selected for programming data, and the memory cell transistors MTrn that are unselected. The memory string MS2 includes only the unselected memory cell transistors MTrn. The word lines 30 and the selection gates 40d and 40s are shared by the memory strings MS1 and MS2.

For example, via the sense amplifier 15, the controller 18 selects the bit line BL1 electrically connected to the memory string MS, and sets the potential of the bit line BL1 to 0 (zero) V. Also, via the sense amplifier 15, the controller 18 applies Vcc to the bit line BL2 connected to the memory string MS2. Further, for example, a potential of 2 V is applied to the source line SL via the source potential supply unit 16. Also, a well potential Vwell is applied to the p-type well 11 via the substrate potential supply unit 17. Vwell is, for example, 6 to 9 V.

Then, via the row decoder 13, the controller 18 applies Vcc to the selection gate 40d and sets the potential of the selection gate 40s to 0 (zero) V. Further, via the row decoder 13, the controller 18 applies Vpp to the word line 30 connected to the memory cell transistor MTrs. Also, via the row decoder 13, the controller 18 applies Vpass to the other word lines 30 connected to the memory cell transistors MTrn.

In the memory string MS1, the selection transistor STD1 is switched to the ON state. On the other hand, the selection transistor STS1 is switched to the OFF state. The memory cell transistors MTrs and MTrn are switched to the ON state. As a result, the channel potential Vch1 of the memory cell transistors MTr becomes 0 V which is the same as the bit line BL1. Then, by the programming voltage Vpp that is applied between the gate-channel for the memory cell transistor MTrs, electric charges are injected from the semiconductor layer 20a into the charge storage layer 21; and the data is programmed to the memory cell transistor MTrs.

In contrast, in the memory string MS2, the selection transistors STD2 and STS2 are switched to the OFF state. Then, the channel potential Vch2 of the memory cell transistors MTr becomes the floating potential. Because Vwell is applied to the p-type well 11 in the example, the channel potential Vch2 is pushed upward to the positive side. As a result, in the memory string MS2, the potential difference between the word line 30 and the channel of the memory cell transistor MTrn becomes small; and the damage of the tunneling insulating layer may be suppressed.

On the other hand, the potential of the p-type well 11 is not affected on the selection transistors STD and STS because the selection transistors STD and STS are provided on the STI 75. In other words, the unintentional change of the potential between the selection gate 40 and each channel of the selection transistors STD and STS is suppressed; and the operations of the selection transistors STD and STS may be stabilized. Also, the potential Vwell of the p-type well 11 may be set to be higher than the substrate potential Vsub shown in FIGS. 5A and 5B. Accordingly, it is possible to further reduce the potential difference between the gate-channel for the memory cell transistors MTrn.

Further, the p-type well 11 may be preferably formed for each memory block MB, reducing the surface area of the p-type well 11. Thereby, it may be possible to make the period of the voltage step-up/step-down for the potential Vwell shorter. Also, the power consumption can be reduced compared to the case where the step-up/step-down is performed for the potential of the entire substrate 10.

### Second Embodiment

FIG. 7 is a schematic cross-sectional view showing a memory cell array 6 of a nonvolatile memory device according to a second embodiment. FIG. 7 is, for example, a cross-sectional view along line 1B-1B shown in FIG. 1B.

The memory cell array 6 includes a first semiconductor layer (hereinbelow, a semiconductor layer 20p) that extends in the X-direction, a first selection gate (hereinbelow, a selection gate 40dp) that is provided on the semiconductor layer 20p and extends in the Y-direction intersecting the X-direction, a second selection gate (hereinbelow, a selection gate 40sp) that is arranged with the selection gate 40dp on the semiconductor layer 20p and extends in the Y-direction, and first word lines (hereinbelow, word lines 30p) that are arranged between the selection gate 40dp and the selection gate 40sp and extend in the Y-direction.

A third selection gate (hereinbelow, a selection gate 40dq) that is provided on the side of the semiconductor layer 20p opposite to the selection gate 40dp and extends in the Y-direction, a fourth selection gate (hereinbelow, a selection gate 40sq) that is provided on the side of the semiconductor layer 20p opposite to the selection gate 40sp and extends in the Y-direction, and second word lines (hereinbelow, word lines 30q) that are provided on the side of the semiconductor layer 20p opposite to the word line 30p and extend in the Y-direction are further included. Also, a second semiconductor layer (hereinbelow, a semiconductor layer 20q) extends in the X-direction between the selection gate 40dq and the semiconductor layer 20p, between the word lines 30q and the semiconductor layer 20p, and between the selection gate 40sq and the semiconductor layer 20q.

The memory cell array 6 further includes the insulating layer 70, first charge storage layers (charge storage layers 21p), second charge storage layers (charge storage layers 21q), a first connecting portion (the drain contact 50), and a second connecting portion (the source contact 60).

The insulating layer 70 is provided between the semiconductor layer 20p and the semiconductor layer 20q. The charge storage layers 21p are provided between the semiconductor layer 20p and the word lines 30p at the portions where the semiconductor layer 20p and the word lines 30p cross. The charge storage layers 21q are provided between the semiconductor layer 20q and the word lines 30q at the portions where the semiconductor layer 20q and the word lines 30q cross.

The drain contact 50 extends through the insulating layer 70 and electrically connects the semiconductor layer 20p to the semiconductor layer 20q. Also, the source contact 60 extends through the insulating layer 70 and electrically connects the semiconductor layer 20p to the semiconductor layer 20q. The semiconductor layer 20p opposes the selection gate 40dp, the charge storage layers 21p, and the selection gate 40sp between a contact portion 20dp electrically connected to the drain contact 50 and a contact portion 20sp electrically connected to the source contact 60. Also, the semiconductor layer 20q opposes the selection gate 40dq, the charge storage layers 21q, and the selection gate 40sq between a contact portion 20dq electrically connected to the drain contact 50 and a contact portion 20sq electrically connected to the source contact 60.

As shown in FIG. 7, the memory cell array 6 includes a foundation layer 90, the semiconductor layer 20p, the insulating layer 70, the semiconductor layer 20q, the bit line BL, and the source line SL. The foundation layer 90 is, for example, a silicon substrate.

For example, the semiconductor layers 20p and 20q and the bit line BL are arranged in order in the Z-direction perpendicular to a top surface of the foundation layer 90. For example, the semiconductor layers 20p and 20q and the bit line BL extend in the X-direction. The source line SL is provided between the semiconductor layer 20q and the bit line BL and extends in, for example, the Y-direction. The insulating layer 70 is provided between the semiconductor layers 20p and 20q.

Memory cell transistors MTrp and selection transistors STDp and STSp are provided between the semiconductor layer 20p and the foundation layer 90. Memory cell transistors MTrq and selection transistors STDq and STSq are provided between the semiconductor layer 20q and the bit line BL.

The memory cell transistor MTrp includes a portion of the semiconductor layer 20p, a portion of the word line 30p, and the charge storage layer 21p. The charge storage layer 21p is provided between the semiconductor layer 20p and the word line 30p. The word line 30p is provided between the charge storage layer 21p and the foundation layer 90 and extends in a direction, e.g., the Y-direction, intersecting the extension direction of the semiconductor layer 20p.

The selection transistor STDp includes a portion of the semiconductor layer 20p, a portion of the selection gate 40dp, and a conductive layer 23dp. The conductive layer 23dp is provided between the semiconductor layer 20p and the selection gate 40dp and is electrically connected to the selection gate 40dp.

The selection transistor STSp includes a portion of the semiconductor layer 20p, a portion of the selection gate 40sp, and a conductive layer 23sp. The conductive layer 23sp is provided between the semiconductor layer 20p and the selection gate 40sp and is electrically connected to the selection gate 40sp. The conductive layers 23dp and 23sp include, for example, the same material as the charge storage layer 21p.

The memory cell transistor MTrq includes a portion of the semiconductor layer 20q, a portion of the word line 30q, and the charge storage layer 21q. The charge storage layer 21q is provided between the semiconductor layer 20q and the word line 30q. The word line 30q is provided between the charge storage layer 21q and the bit line BL and extends in a direction, e.g., the Y-direction, intersecting the extending direction of the semiconductor layer 20q.

The selection transistor STDq includes a portion of the semiconductor layer 20q, a portion of the selection gate 40dq, and a conductive layer 23dq. The conductive layer 23dq is provided between the semiconductor layer 20q and the selection gate 40dq and is electrically connected to the selection gate 40dq.

The selection transistor STSq includes a portion of the semiconductor layer 20q, a portion of the selection gate 40sq, and a conductive layer 23sq. The conductive layer 23sq is provided between the semiconductor layer 20q and the selection gate 40sq and is electrically connected to the selection gate 40sq. The conductive layers 23dq and 23sq include, for example, the same material as the charge storage layer 21q.

The bit line BL is electrically connected to the semiconductor layers 20p and 20q via the drain contact 50 on the drain side of the selection transistor STD. For example, the drain contact 50 extends through the semiconductor layer 20q and the insulating layer 70 and reaches the semiconductor layer 20p. The drain contact 50 contacts the contact portion 20dp provided in the semiconductor layer 20p and the contact portion 20dq provided in the semiconductor layer 20q.

The source line SL is electrically connected to the semiconductor layers 20p and 20q via the source contact 60 on the source side of the selection transistor STS. For example, the source contact 60 extends through the semiconductor layer 20q and the insulating layer 70 and reaches the semiconductor layer 20p. The source contact 60 contacts the contact portion 20sp provided in the semiconductor layer 20p and the contact portion 20sq provided in the semiconductor layer 20q.

An insulating layer 71 that covers the memory cell transistors MTrp and the selection transistors STDp and STSp is provided between the semiconductor layer 20p and the foundation layer 90. An insulating layer 73 that covers the memory cell transistors MTrq and the selection transistors STDq and STSq is provided between the bit line BL and the semiconductor layer 20q.

In the example as well, the memory cell transistors MTr include the insulating layer 27 between the semiconductor layer 20 and the charge storage layers 21. Also, the memory cell transistors MTr include the insulating layer 29 between the charge storage layers 21 and the word lines 30. The selection transistors STD and STS include the insulating layer 27 between the semiconductor layer 20 and the conductive layers 23. Also, the selection transistors STD and STS include the insulating layer 29 between the conductive layers 23 and the selection gates 40. The conductive layers 23 are electrically connected to the selection gates 40 by the connecting portions 24 extending through the insulating layer 29.

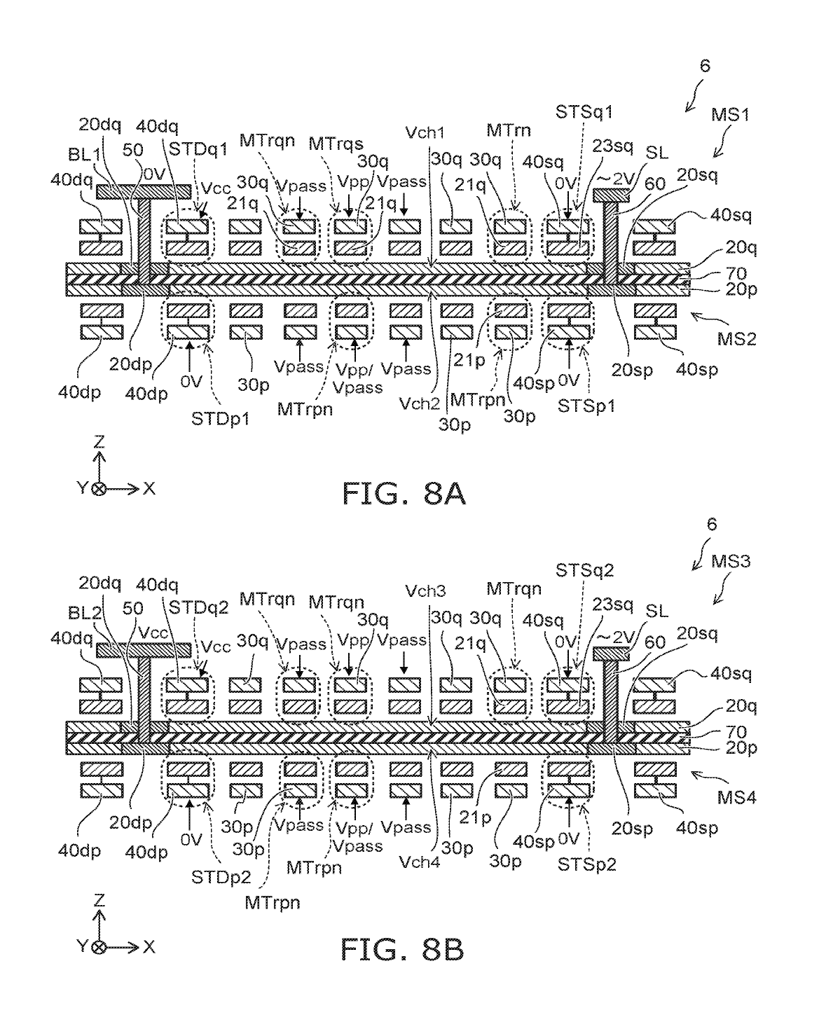

FIGS. 8A and 8B are schematic cross-sectional views showing operations of the memory cell array 6 according to the second embodiment. FIGS. 8A and 8B show the gate potentials V_{GM}, V_{GD}, and V_{GS}, the potential of the bit line BL, and the potential of the source line SL when programming data.

FIG. 8A shows a cross section including the memory string MS1 and the memory string MS2; and FIG. 8B shows a cross section including a memory string MS3 and a memory string MS4. The memory string MS1 includes a memory cell transistor MTrqs that is selected for programming data, and memory cell transistors MTrqn that are unselected. The memory strings MS2, MS3, and MS4 include only the unselected memory cell transistors MTrpn and MTrqn. The word lines 30q and the selection gates 40dq and 40sq are shared by the memory strings MS1 and MS3. The word lines 30p and the selection gates 40dp and 40sp are shared by the memory strings MS2 and MS4.

For example, via the sense amplifier 15, the controller 18 selects the bit line BL1 electrically connected to the memory string MS1 and sets the potential of the bit line BL1 to 0 (zero) V. Also, via the sense amplifier 15, the controller 18 applies Vcc to the bit line BL2 connected to the memory string MS2. Further, for example, a potential of 2 V is applied to the source line SL via the source potential supply unit 16.

Then, via the row decoder 13, the controller 18 applies Vcc to the selection gate 40dq and sets the potentials of the selection gates 40dp, 40sp, and 40sq to 0 (zero) V. Further, via the row decoder 13, the controller 18 applies Vpp to the word line 30q connected to the memory cell transistor MTrqs. Also, via the row decoder 13, the controller 18 applies Vpass to the other word lines 30p and 30q connected to the memory cell transistors MTrpn and MTrqn.

Here, there are cases where Vpp is applied to the word line 30p connected to the memory cell transistor MTrpn that is positioned, with the semiconductor layers 20p and 20q interposed, on the side opposite to the memory cell transistor MTrqs. In other words, the word line 30p and the word line 30q that oppose each other with the semiconductor layers 20p and 20q interposed may be electrically connected and may have the same potential applied. Thereby, for example, the configuration of the row decoder 13 can be simplified.

In the memory string MS1, a selection transistor STDq1 is switched to the ON state. On the other hand, a selection transistor STSq1 is switched to the OFF state. Also, the memory cell transistors MTrq are switched to the ON state. As a result, the channel potential Vch1 of the memory cell transistors MTr is 0 V which is the same as that of the bit line BL1. Then, by the programming voltage Vpp that is applied between the gate-channel for the memory cell transistor MTrqs, electric charges are injected from the semiconductor layer 20q into the charge storage layer 21q; and the data is programmed to the memory cell transistor MTrqs.

In contrast, in the memory string MS2, selection transistors STDp1 and STSp1 are switched to the OFF state. Accordingly, the channel potential Vch2 of the memory cell transistors MTrp is the floating potential. For example, the channel potential Vch2 is pulled upward by the potential V_{GM} of the word line 30p. As a result, in the memory string MS2, the potential difference between the word line 30p and the channel of the memory cell transistor MTrpn becomes small.

In the memory string MS3, a selection transistor STDq2 and a selection transistor STSq2 are switched to the OFF state. Then, the channel potential Vch3 of the memory cell transistors MTrq is the floating potential. Also, in the memory string MS4, a selection transistor STDp2 and a selection transistor STSp2 are switched to the OFF state. Then, a channel potential Vch4 of the memory cell transistors MTrp is the floating potential. Further, a channel potential Vch3 and the channel potential Vch4 act on each other and increase the potentials of each other. Thereby, in the memory strings MS3 and 4, it is possible to set the potential difference between the gate and channel in each of the memory cell transistors MTrp and MTrq to be small; and, for example, the damage of the tunneling insulating layer may be suppressed in the unselected memory cell transistors MTrpn and MTrqn to which Vpp is applied.

By providing the insulating layer 70 between the semiconductor layer 20p and the semiconductor layer 20q in the embodiment as recited above, the potential difference between the gate and channel in the unselected memory cell transistors MTrpn and MTrqn is set to be small, when programming data; and the damage of the tunneling insulating layer may be suppressed. Also, in the embodiment, the substrate potential supply unit 17 of the peripheral circuit can be omitted.

### Third Embodiment

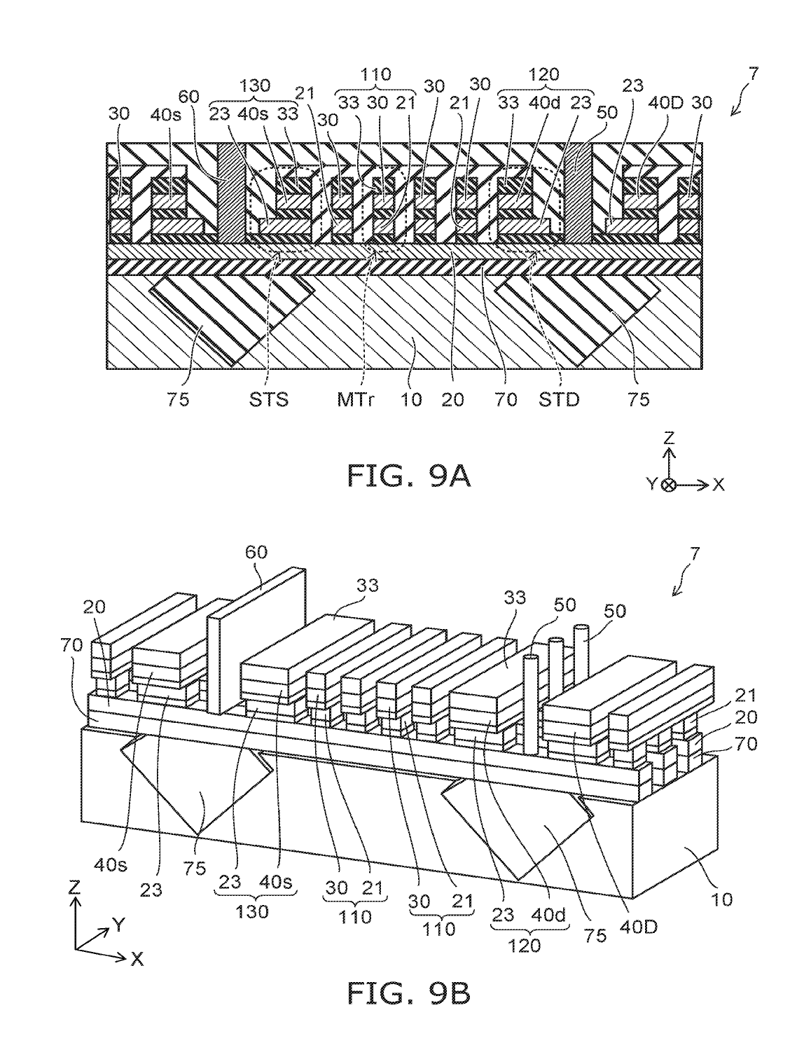

FIGS. 9A and 9B are schematic views showing a memory cell array 7 according to a third embodiment. FIG. 9A is a schematic view showing a cross section along line 1B-1B of FIG. 1B. FIG. 9B is a perspective view showing the memory cell array 7.

As shown in FIG. 9A, the memory cell array 7 includes a semiconductor layer 20, first stacked bodies (hereinbelow, stacked bodies 110), a second stacked body (hereinbelow, a stacked body 120), and a third stacked body (hereinbelow, a stacked body 130). The semiconductor layer 20 is provided on a substrate 10 with an insulating layer 70 interposed. The semiconductor layer 20 has a stripe configuration extending in the X-direction. The stacked bodies 110, 120, and 130 are provided on the semiconductor layer 20. For example, the stacked body 120 and the stacked body 130 are arranged in the X-direction; and the multiple stacked bodies 110 are arranged between the stacked body 120 and the stacked body 130.

A stacked body 110 includes, for example, a charge storage layer 21, a word line 30, and a capping layer 33. The stacked body 120 includes, for example, a conductive layer 23, a selection gate 40d, and a capping layer 33. The stacked body 130 includes, for example, a conductive layer 23, a selection gate 40s, and a capping layer 33.

As shown in FIG. 9B, the semiconductor layers 20 are arranged in the Y-direction. The word line 30, the selection gates 40d and 40s, and the capping layer 33 extend in the Y-direction. The charge storage layer 21 is provided between the semiconductor layer 20 and the word line 30 at the portion where the semiconductor layer 20 and the word line 30 cross. Charge storage layers 21 are separated from each other in the X-direction and the Y-direction. The conductive layer 23 is provided between the semiconductor layer 20 and the selection gate 40 at the portion where the semiconductor layer 20 and the selection gate 40 cross. Conductive layers 23 are separated from each other in the Y-direction.

The memory cell transistor MTr is provided at the portion where the semiconductor layer 20 and the word line 30 cross and includes a portion of the semiconductor layer 20, the charge storage layer 21, and a portion of the word line 30. The selection transistor STD is provided at the portion where the semiconductor layer 20 and the selection gate 40d cross and includes a portion of the semiconductor layer 20, the conductive layer 23, and a portion of the selection gate 40d. The selection transistor STS is provided at the portion where the semiconductor layer 20 and the selection gate 40s cross and includes a portion of the semiconductor layer 20, another conductive layer 23, and a portion of the selection gate 40s.

The memory cell array 7 includes the drain contacts 50 and the source contact 60. The drain contacts 50 are provided on the drain side of the selection transistors STD. Each drain contact 50 is electrically connected to the semiconductor layer 20. The drain contact 50 electrically connects the not-shown bit line BL to the semiconductor layer 20. The source contact 60 is provided on the source side of the selection transistors STS. The source contact 60 extends in the Y-direction and is electrically connected to the multiple semiconductor layers 20.

The memory cell array 7 further includes the insulating layer 75 provided in the substrate 10. The insulating layer 75 is provided under the selection transistors STD and the drain contacts 50 and extends in, for example, the Y-direction. Also, another insulating layer 75 is provided under the selection transistors STS and the source contact 60 and extends in, for example, the Y-direction. The insulating layer 75 contacts the insulating layer 70.

By providing the insulating layers 75 under the selection transistors STD and STS in the embodiment, the unintentional change of the potential between a gate and a channel in each of the selection transistors STD and STS is suppressed, when reading data; and the operations of the selection transistors STD and STS are stabilized. In other words, the increase of the channel potential due to the potential applied to the substrate 10 may be suppressed in the selection transistors STD and STS.

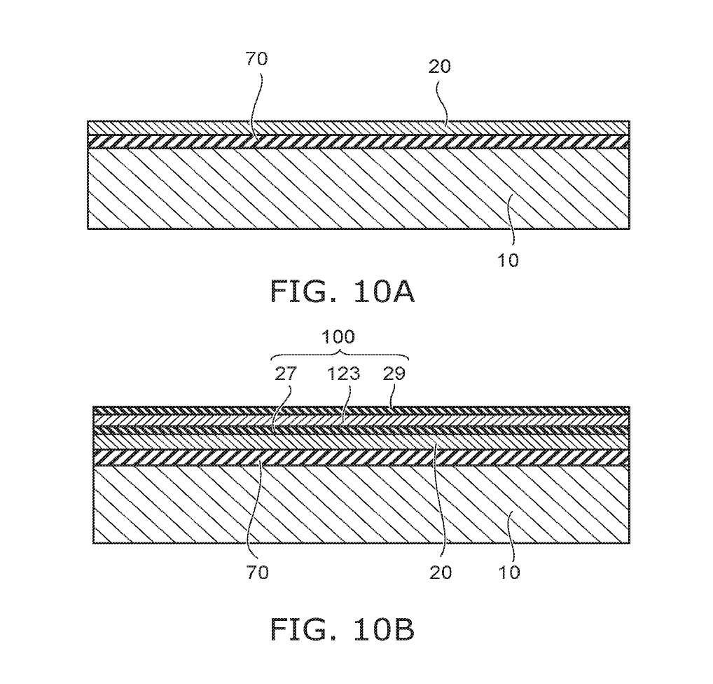

A method for manufacturing the memory cell array 7 according to the third embodiment will now be described with reference to FIGS. 10A to 22E. FIGS. 10A to 22E are schematic cross-sectional views showing the manufacturing processes of the memory cell array 7 in order.

As shown in FIG. 10A, the semiconductor layer 20 is provided on the substrate 10 with the insulating layer 70 interposed. In other words, the semiconductor layer 20 and the insulating layer 70 have an SOI structure (Silicon on Insulator). The substrate 10 is, for example, a silicon substrate; and the insulating layer 70 is, for example, a silicon oxide layer. Also, the insulating layer 70 may be a silicon oxide layer having nitrogen added. The semiconductor layer 20 is, for example, a silicon layer. The semiconductor layer 20 may contain, for example, silicon in which amorphous silicon is crystallized. Silicon-germanium (SiGe) also may be used as the material of the semiconductor layer 20.

As shown in FIG. 10B, a stacked body 100 is provided on the semiconductor layer 20, in which the insulating layer 27, a conductive layer 123, and the insulating layer 29 are formed in order. The insulating layers 27 and 29 are, for example, silicon oxide films. For example, the conductive layer 123 has a stacked structure including a polysilicon layer, an insulating layer, and a metal layer.

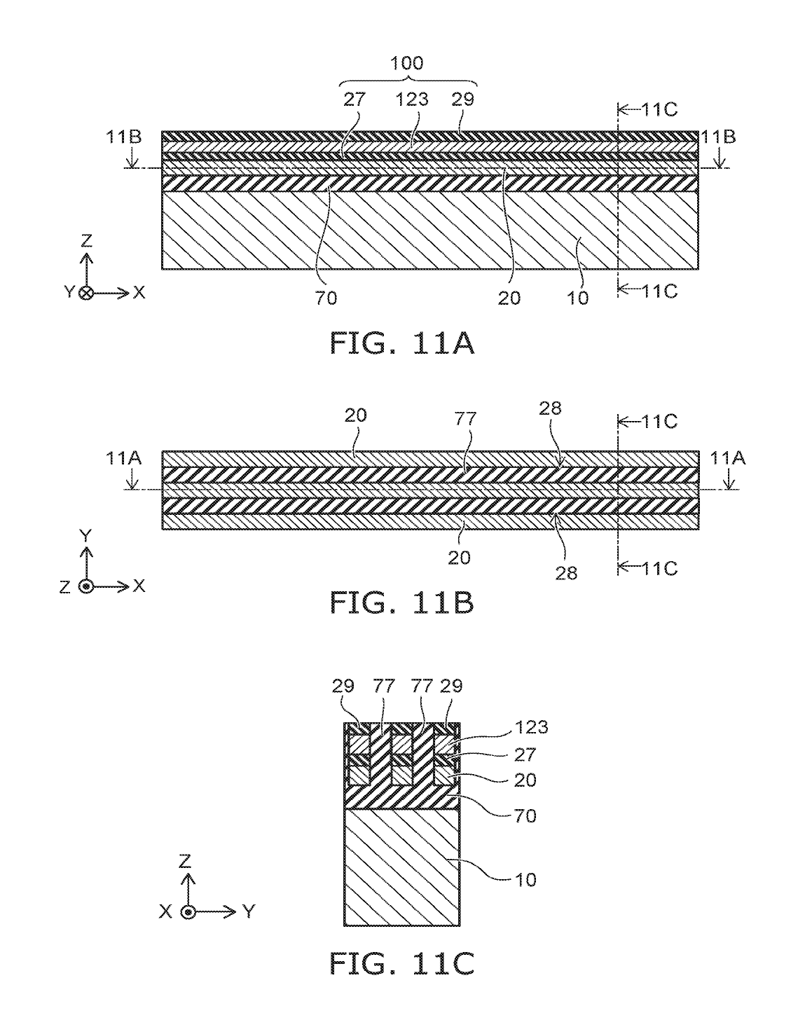

As shown in FIGS. 11A to 11C, the stacked body 100 is divided into multiple stripes extending in the X-direction. FIG. 11A is a schematic cross-sectional view along line 11A-11A shown in FIG. 11B. FIG. 11B is a schematic cross-sectional view along line 11B-11B shown in FIG. 11A. FIG. 11C is a schematic cross-sectional view along line 11C-11C shown in FIGS. 11A and 11B. In the drawings hereinbelow, the cross sections corresponding to the drawings are illustrated by single dot-dash lines.

For example, the stacked body 100 is divided by making trenches 28 from the upper surface of the stacked body 100 to have a depth reaching the insulating layer 70. As shown in FIG. 11B, the trenches 28 extend in the X-direction. Also, as shown in FIGS. 11B and 11C, an insulating layer 77 is filled into the interior of the trenches 28. The insulating layer 77 is so-called STI (Shallow Trench Isolation) and is linked to the insulating layer 70. The insulating layer 77 is, for example, a silicon oxide layer.

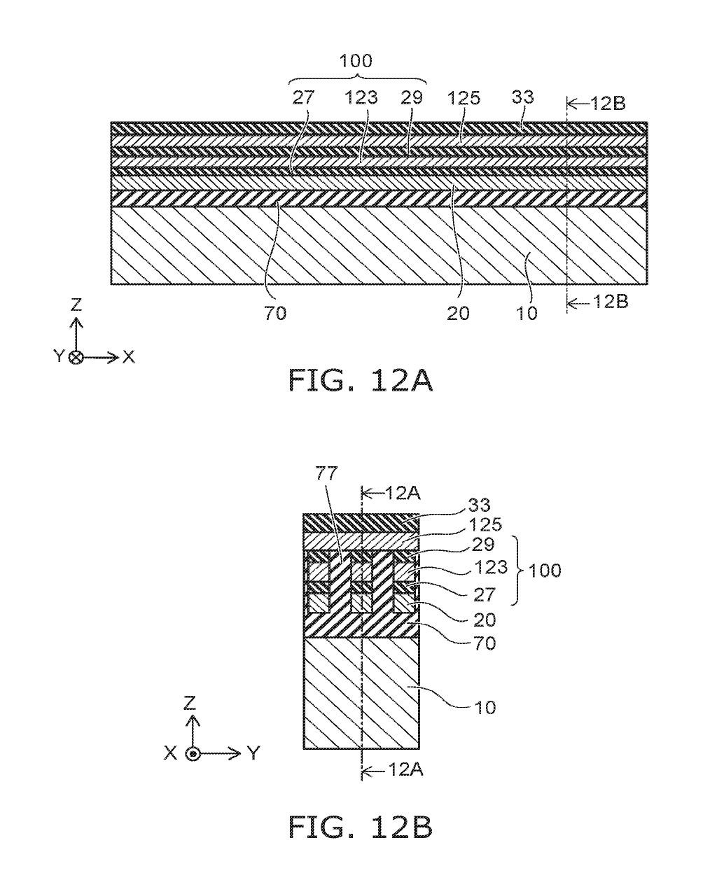

As shown in FIGS. 12A and 12B, a conductive layer 125 and the capping layer 33 are formed on the stacked body 100 divided by the insulating layer 77. For example, the conductive layer 125 has a stacked structure including a metal oxide layer and a metal layer. The capping layer 33 is, for example, a silicon oxide film or a silicon nitride film.

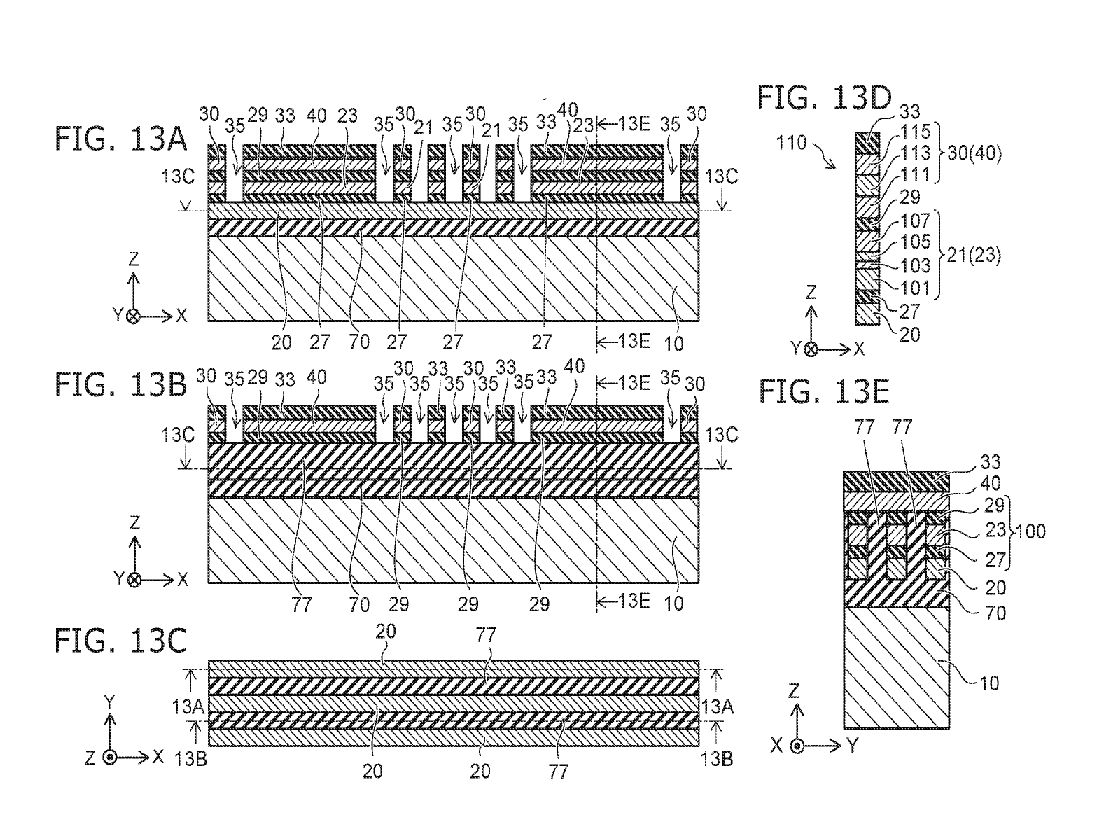

As shown in FIGS. 13A and 13B, slits 35 are formed to divide the stacked body 100, the conductive layer 125, and the capping layer 33. The slits 35 are provided from the upper surface of the capping layer 33 to a depth reaching the semiconductor layer 20 and the insulating layer 77 and extend in the Y-direction. Thereby, the conductive layer 123 is divided into the charge storage layers 21 and the conductive layers 23. Also, the conductive layer 125 is divided into the word lines 30 and the selection gates 40.

As shown in FIG. 13D, for example, the charge storage layers 21 and the conductive layers 23 have structures in which a polysilicon layer 101, a silicon nitride layer 103, a ruthenium (Ru) layer 105, and a hafnium oxide layer 107 are stacked in order. Also, for example, the word lines 30 and the selection gates 40 have structures in which a hafnium oxide layer 111, a tantalum oxynitride layer 113, and a tungsten layer 115 are stacked in order.

As shown in FIG. 13E, the conductive layers 23 are separated from each other by the insulating layer 77 in the Y-direction. Similarly, the charge storage layers 21 also are separated from each other by the insulating layer 77 in the Y-direction. On the other hand, the selection gates 40 extend in the Y-direction on the insulating layers 29 and 77. Similarly, the word lines 30 also extend in the Y-direction on the insulating layers 29 and 77.

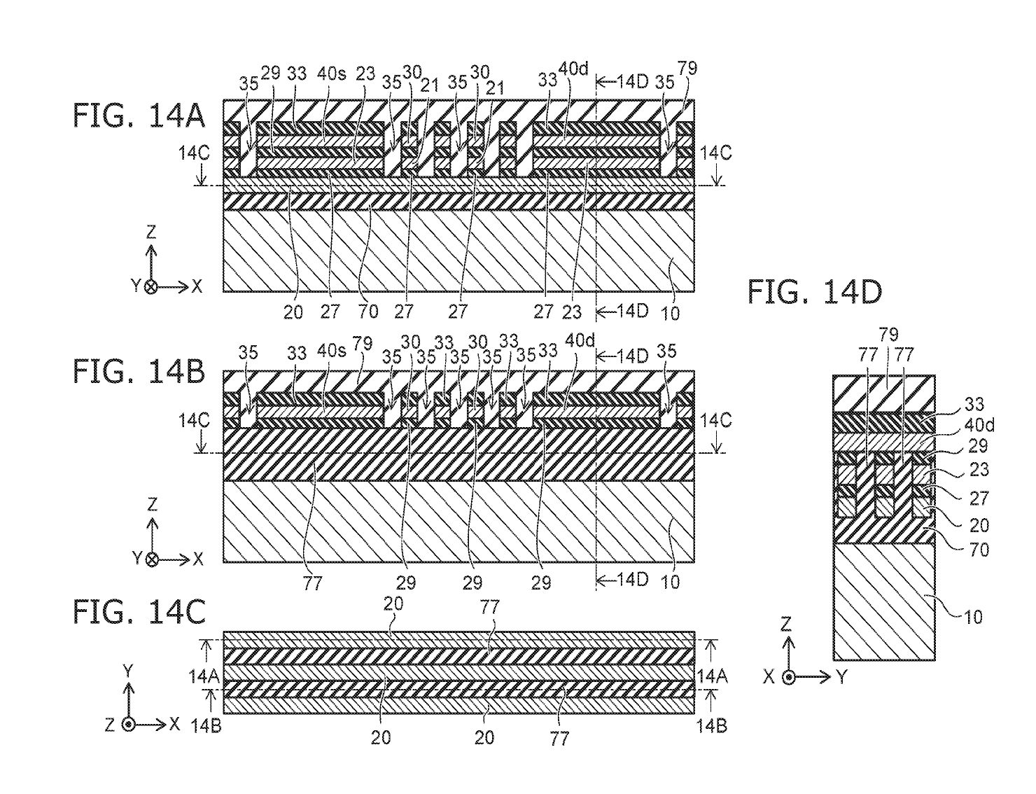

An insulating layer 79 is formed as shown in FIGS. 14A to 14D. The insulating layer 79 covers the capping layers 33 and is filled into the interiors of the slits 35. The insulating layer 79 is, for example, a silicon oxide film.

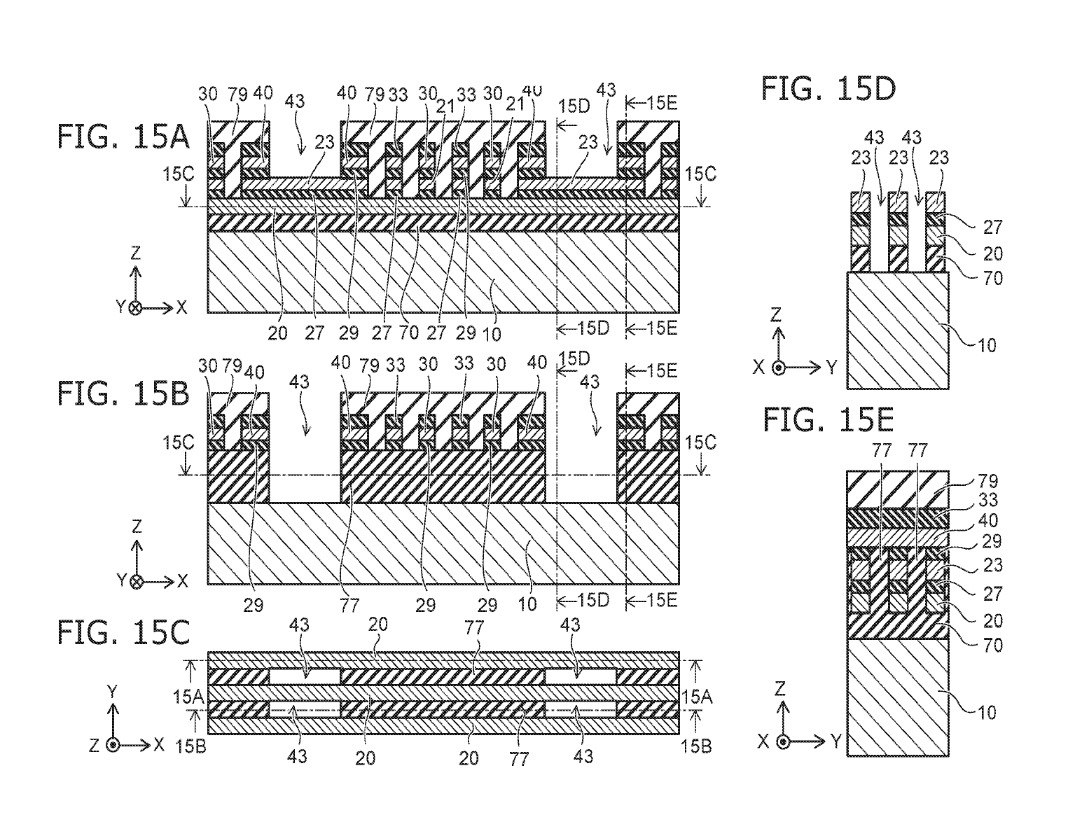

As shown in FIGS. 15A to 15E, trenches 43 are formed to divide the selection gates 40. As shown in FIG. 15A, the trenches 43 are made above the semiconductor layers 20 from the upper surface of the insulating layer 79 to a depth reaching the conductive layers 23. As shown in FIG. 15B, the trenches 43 are provided between the mutually-adjacent semiconductor layers 20 from the upper surface of the insulating layer 79 to a depth reaching the substrate 10. As shown in FIG. 15D, between the mutually-adjacent semiconductor layers 20, the insulating layer 70 and the insulating layer 77 are removed and the substrate 10 is exposed at the bottom surfaces of the trenches 43.

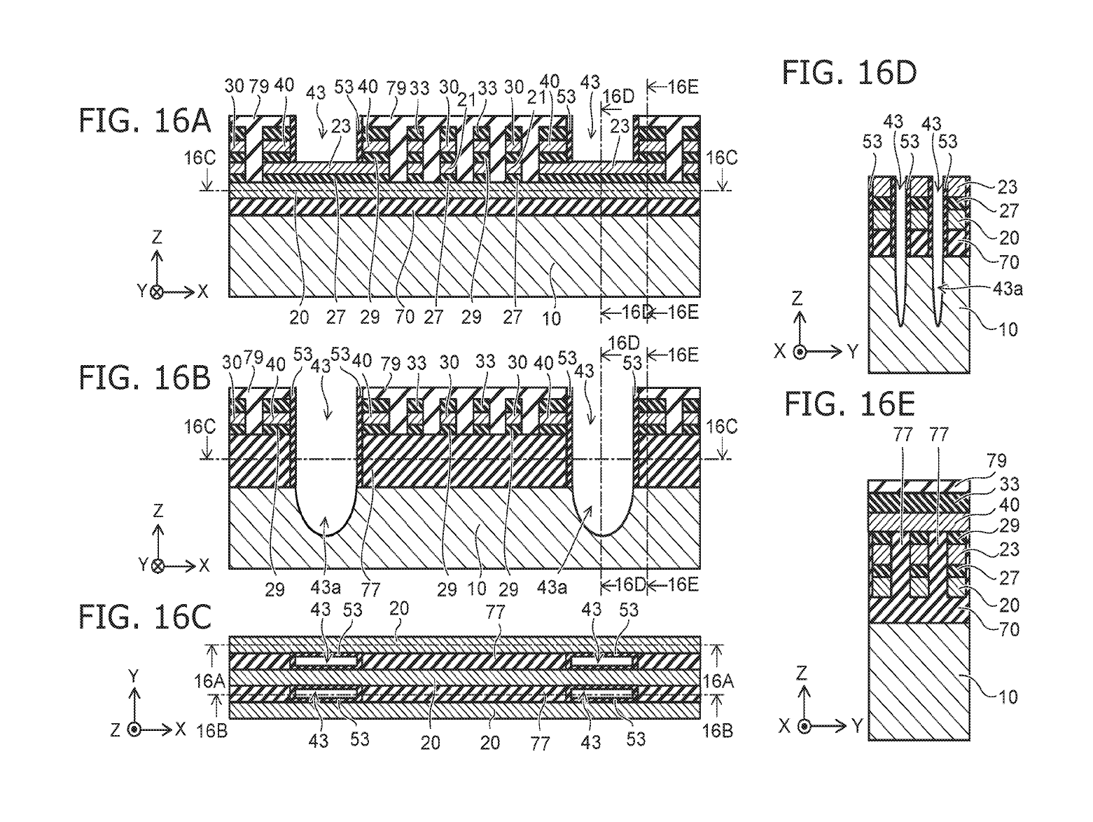

As shown in FIGS. 16A to 16E, after forming an insulating layer 53 that covers the side walls of the trenches 43, a part of the substrate 10 is removed, which is exposed at the bottom surfaces of the trenches 43. For example, the insulating layer 53 covers the conductive layers 23 and the selection gates 40 exposed at the wall surfaces of the trenches 43 and protects the conductive layers 23 and the selection gates 40 while the substrate 10 is removed. The insulating layer 53 is, for example, a silicon oxide layer.

For example, the insulating layer 53 that covers the upper surface of the insulating layer 79 and the inner surfaces of the trenches 43 is formed using ALD (Atomic Layer Deposition) or LPCVD (Low Pressure Chemical Vapor Deposition). Then, for example, the insulating layer 53 that is deposited on the bottom surfaces of the trenches 43 is removed using anisotropic dry etching, leaving the portions formed on the side walls of the trenches 43. Then, for example, the substrate 10 is removed to a prescribed depth using dry etching.

At this time, for example, at the exposed portions of the conductive layers 23 above the semiconductor layers 20, the hafnium oxide layers 107 which are the uppermost layers of the conductive layers 23 are exposed (referring to FIG. 13D). Accordingly, it is favorable for the substrate 10 to be removed using conditions at which hafnium oxide is etched with lower rate.

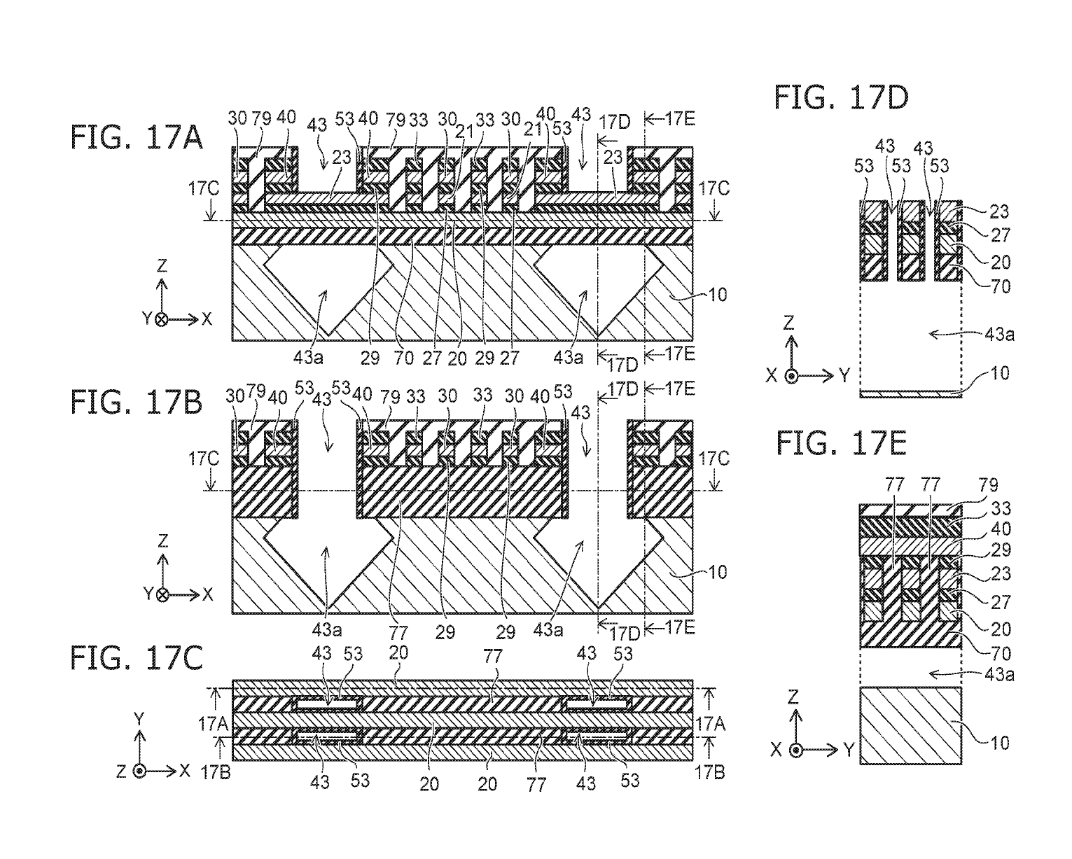

As shown in FIGS. 17A to 17E, hollows (hollows) 43a are caused to spread by performing wet etching of the substrate 10 via the trenches 43. For example, the substrate 10 is a silicon substrate having a (100) plane as a major surface. The etchant includes, for example, potassium hydroxide (KOH). At this time, the insulating layer 53, the insulating layer 70, the insulating layer 77, and the conductive layers 23 that cover the side walls of the trenches 43 are resistant to the etchant. Accordingly, only the substrate 10 is etched.

In the wet etching, for example, the etching rate of the (111) plane of the silicon is slower than the etching rate of the (100) plane. Therefore, the hollows 43a are formed at the lower portions of the trenches 43, which are surrounded by the (111) surfaces of silicon. Also, the hollows 43a spread below the selection gates 40 positioned at the two sides of the trenches 43. The final size of the hollows 43a is dependent on the depth of the hollows 43a made by the dry etching. In other words, the hollows 43a may be formed so as to spread into the entire region under the selection gate 40 by controlling the depth of the dry etching.

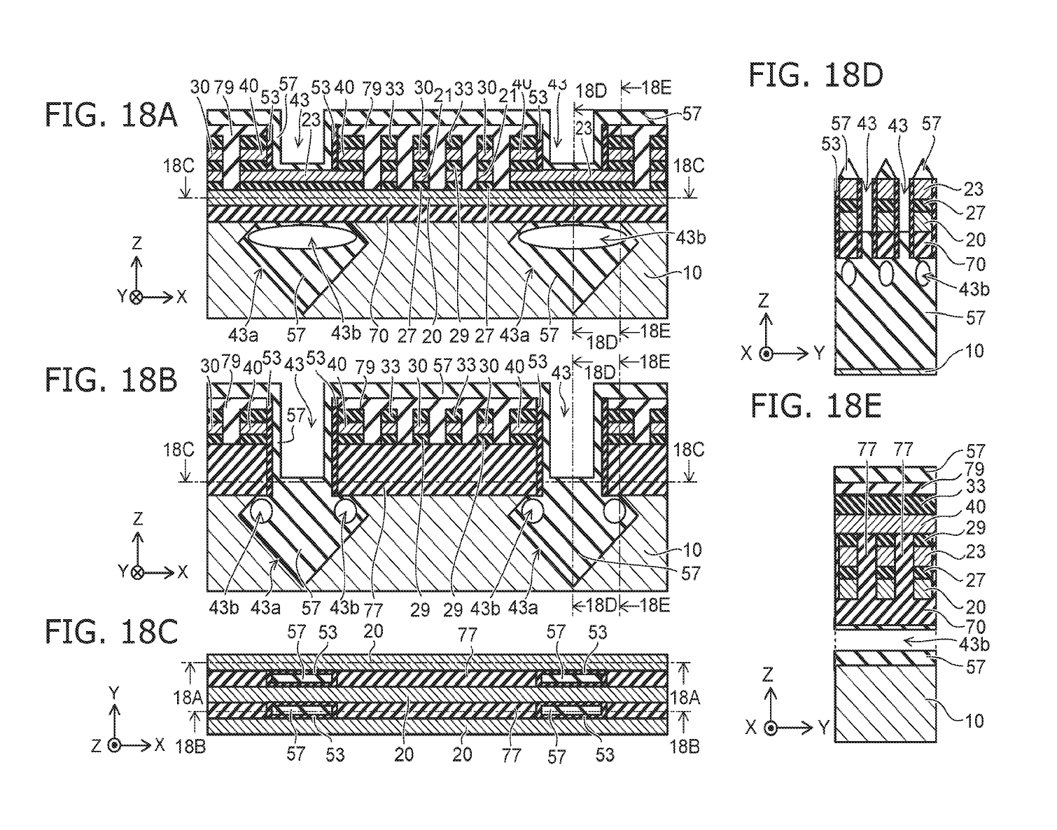

As shown in FIGS. 18A to 18E, an insulating layer 57 is formed in the interiors of the hollows 43a. The insulating layer 57 is, for example, a silicon oxide layer formed using high-density plasma CVD (HDP-CVD). The insulating layer 57 covers the inner surfaces of the hollows 43a. Also, cavities 43b are made in the insulating layer 57 because the insulating layers 70 and 77 become eaves for the high-density plasma excited above the substrate 10. For example, the cavities 43b are positioned below the selection gates 40. Also, the cavities 43b are made under the semiconductor layers 20 below the selection gates 40. For example, the insulating layer 57 that is formed below the selection gates 40 reduces the capacitive coupling between the substrate 10 and the semiconductor layers 20. Also, the cavities 43b further reduce the capacitive coupling.

The insulating layer 57 is formed also on the side walls of the trenches 43 and on the upper surface of the insulating layer 79. Although the insulating layer 57 is formed on the conductive layers 23 exposed inside the trenches 43, the thickness of the insulating layer 57 in the Z-direction is thinner than the thickness in the Z-direction of the portion of the insulating layer 57 formed on the insulating layer 79, for example, since the width in the Y-direction of the conductive layers 23 is narrow.

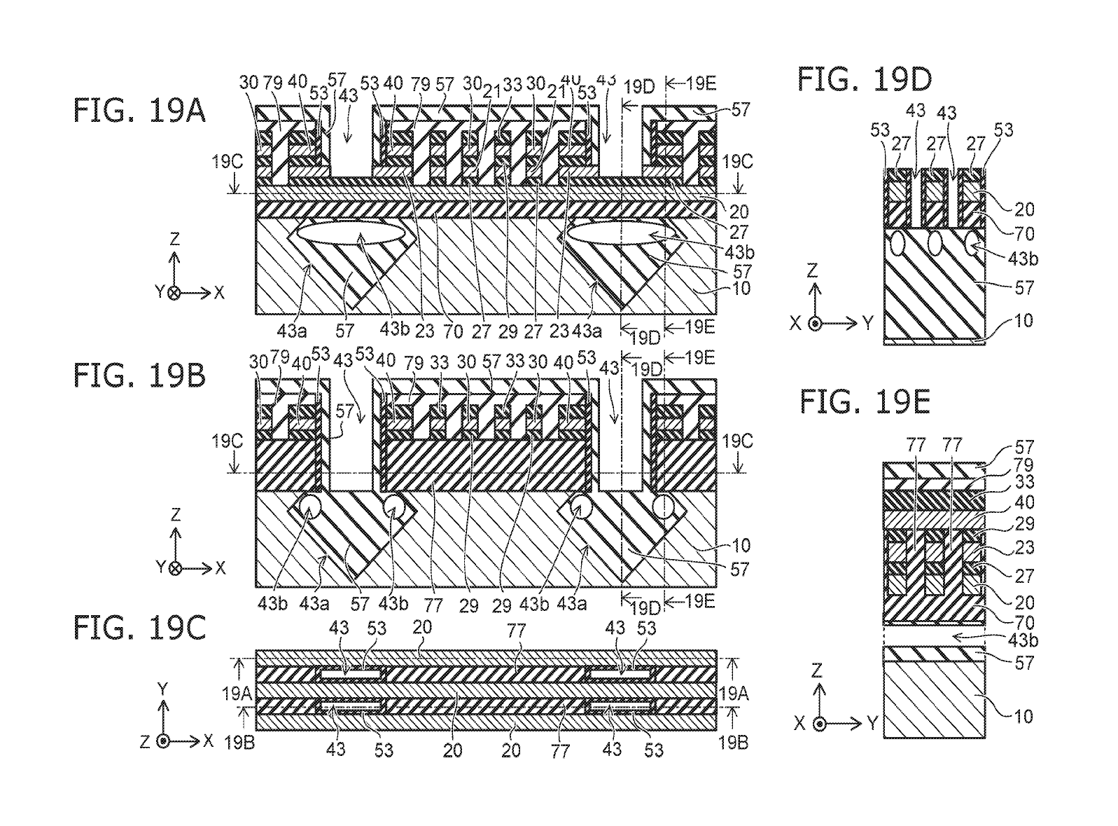

As shown in FIGS. 19A to 19D, the conductive layers 23 are removed via the trenches 43. For example, the insulating layer 57 that is formed on the conductive layers 23 is selectively removed using anisotropic dry etching. Further, the conductive layers 23 that are exposed inside the trenches 43 are selectively removed using anisotropic dry etching; and each conductive layer 23 is divided into two portions that are positioned at both sides of the trenches 43.

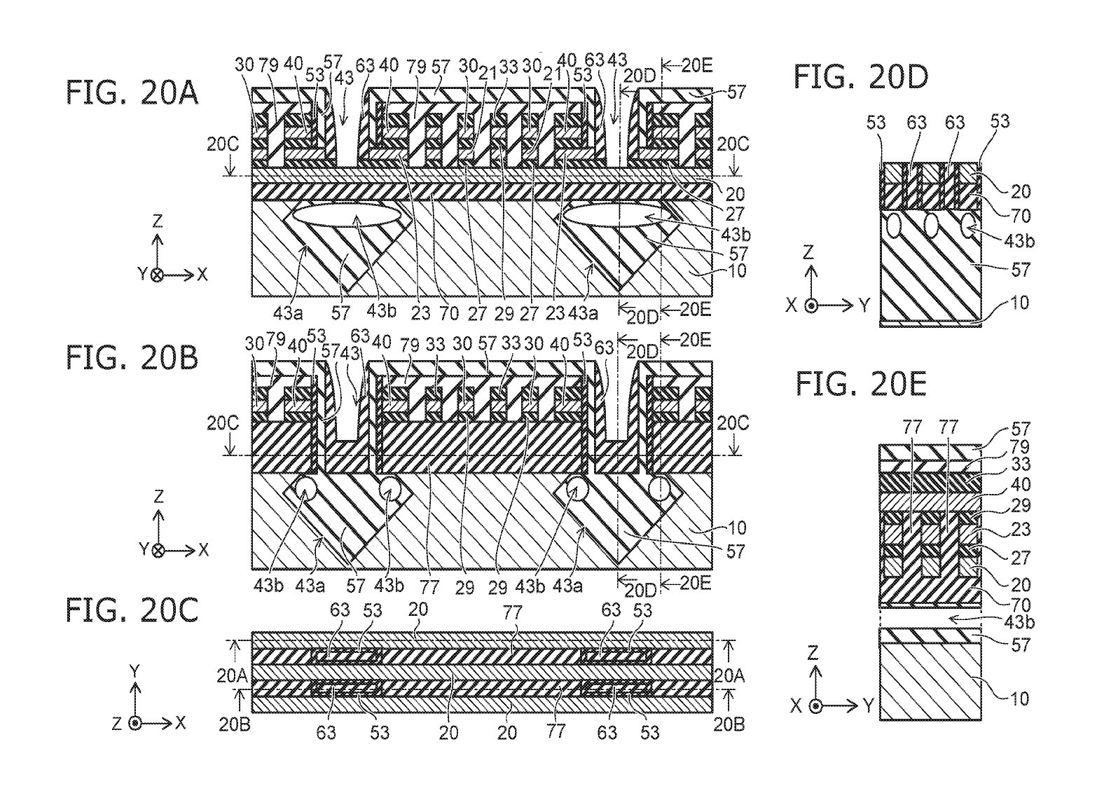

As shown in FIGS. 20A to 20E, sidewalls 63 are further formed in the interiors of the trenches 43. For example, the sidewalls 63 are formed by forming a silicon oxide layer that covers the upper surface of the insulating layer 57 and the inner surfaces of the trenches 43 using LPCVD and by subsequently removing the silicon oxide layer that is formed on the upper surface of the insulating layer 57 and the bottom surfaces of the trenches 43 by anisotropic dry etching, leaving the portions on the trench wall as the sidewalls 63.

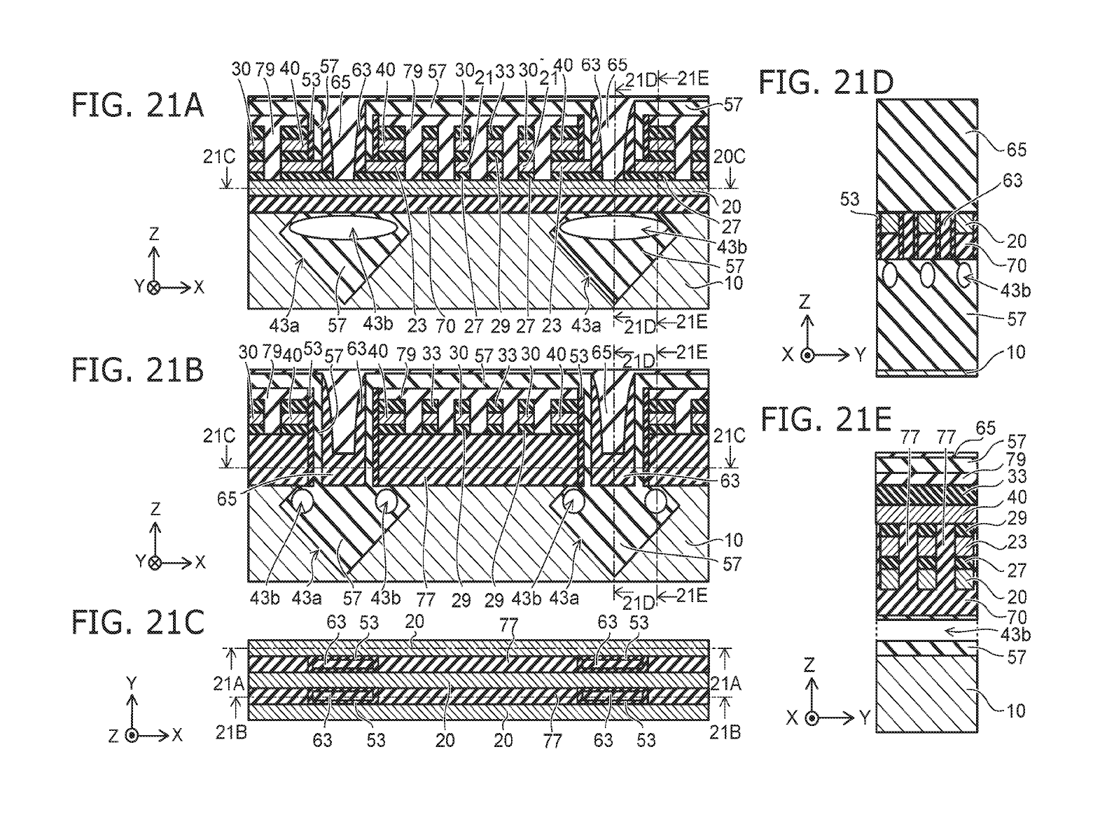

As shown in FIGS. 21A to 21E, an insulating layer 65 is formed to fill the interiors of the trenches 43. Also, the top surface of the insulating layer 65 is planarized using, for example, CMP (Chemical Mechanical Polishing).

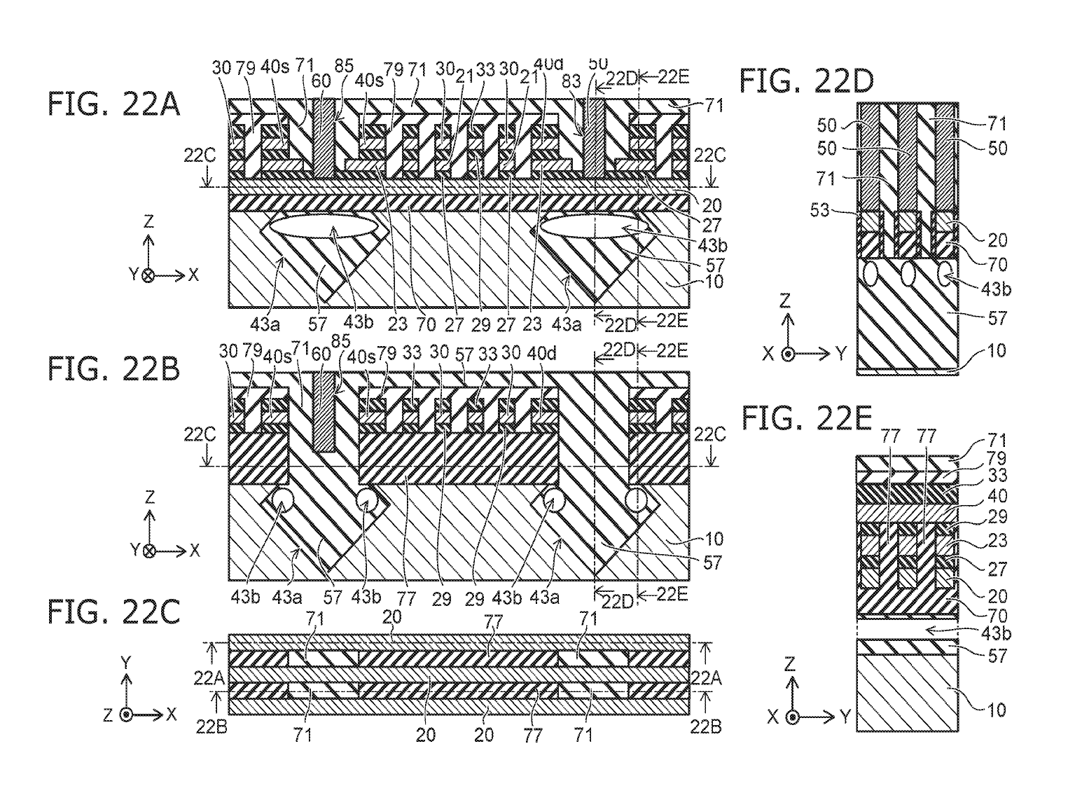

As shown in FIGS. 22A to 22E, contact holes 83 and 85 are made from the top surface of the insulating layer 71 to a depth reaching the semiconductor layers 20; and the drain contacts 50 and the source contact 60 are formed in the interiors of the contact holes 83 and 85. Here, the insulating layers 57 and 53, the sidewalls 63 and the insulating layer 65 are merged into the insulating layer 71 for convenience. The the selection gates 40d are positioned at two sides of the drain contacts 50. The selection gates 40s are positioned at two sides of the source contact 60.

For example, the contact holes 83 and 85 are formed by selectively removing the insulating layer 71 using RIE (Reactive Ion Etching). Further, for example, an n-type impurity is ion-implanted into the semiconductor layers 20 exposed at the bottom surfaces of the contact holes 83 and 85; and subsequently, activating is carried out using RTA (Rapid Thermal Annealing). Thereby, the contact resistances are reduced between the semiconductor layers 20 and the drain contacts 50 and between the semiconductor layers 20 and the source contact.

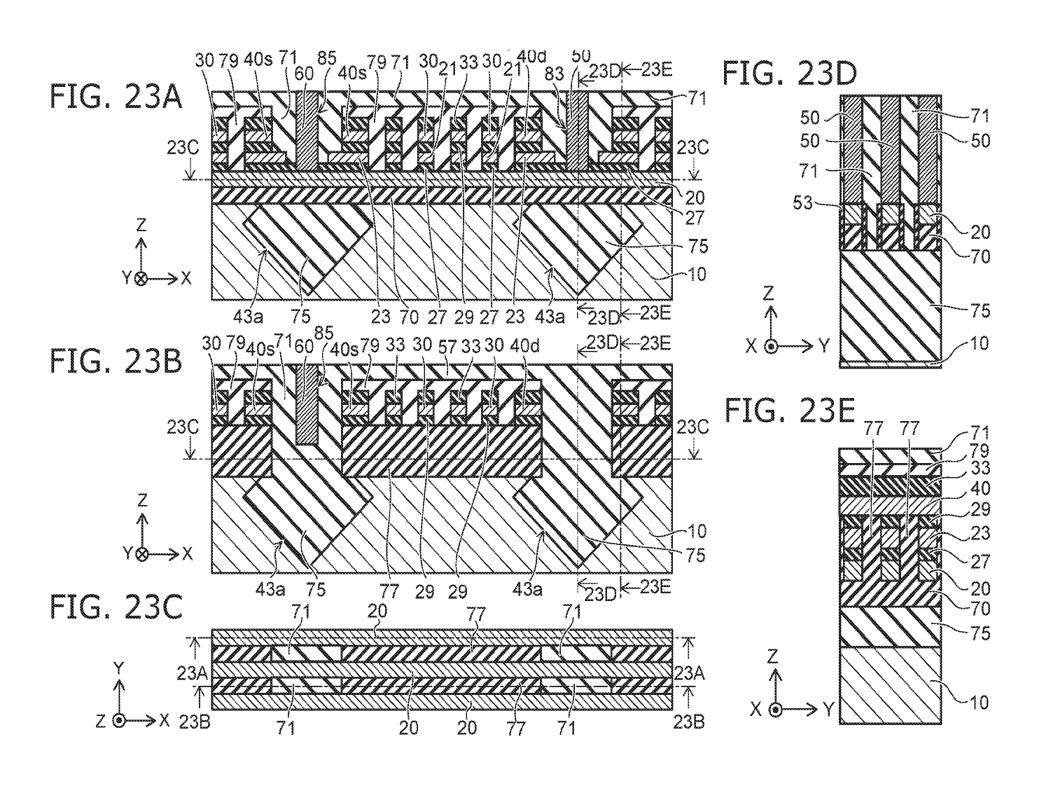

As shown in FIGS. 23A to 23E, the insulating layer 75 without the cavities 43b may be formed in the interiors of the hollows 43a. For example, the structure that has no cavities 43b can be formed by forming a silicon oxide layer in the interiors of the hollows 43a using LPCVD.

By providing the insulating layer 75 below the selection transistors STD and STS in the embodiment, the capacitive coupling can be reduced between the substrate 10 and the channels of the selection transistors STD and STS. Thereby, it is possible to suppress the unintentional change of the channel potential due to the potential applied to the substrate 10 when programming data; and the selection transistors STD and STS can operate stably.

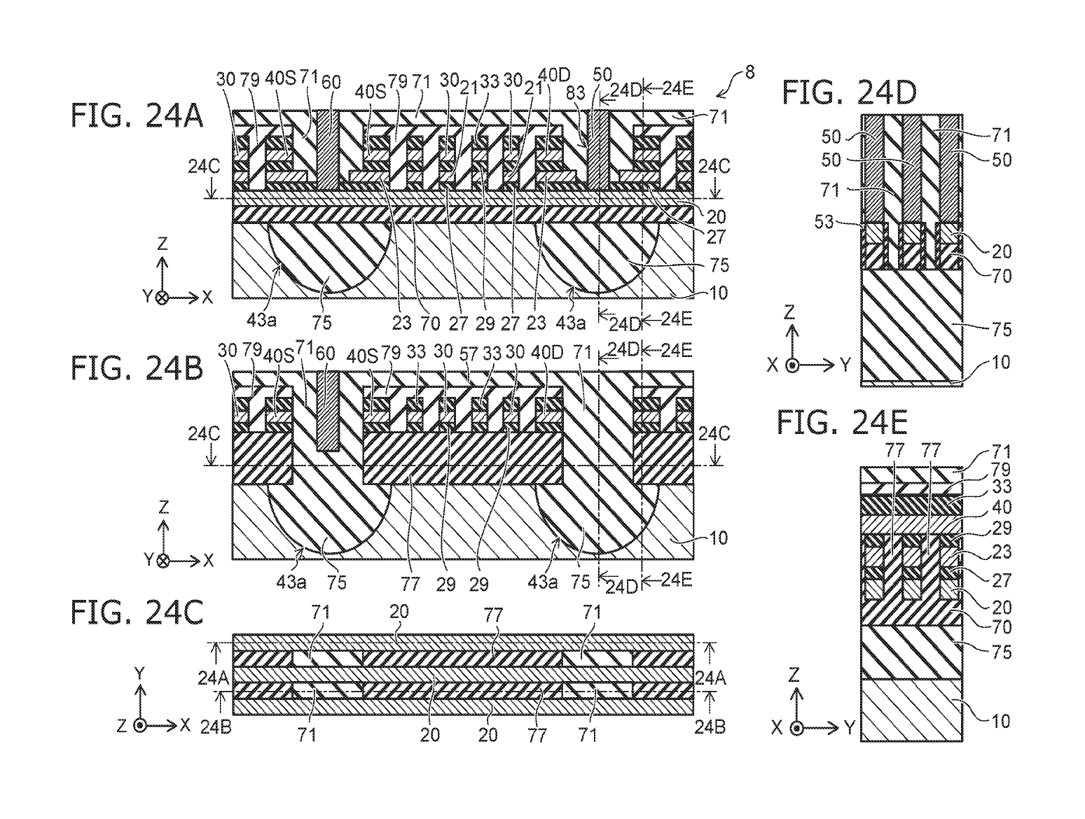

FIGS. 24A to 24E are schematic cross-sectional views showing a memory cell array 8 according to a variation of the third embodiment. In the memory cell array 8, for example, the insulating layer 75 has a cross section having a semicircular configuration or a semielliptical configuration. For example, such a configuration is obtained by expanding the hollows 43a using CDE (Chemical Dry Etching) instead of wet etching using KOH. In other words, the hollows 43a that have cross sections having semicircular configurations or semielliptical configurations can be made by removing the substrate 10 using isotropical etching such as CDE. For example, the expanded width of the insulating layer 75 positioned below the selection transistors STD and STS may be controlled by the time of the etching using CDE.

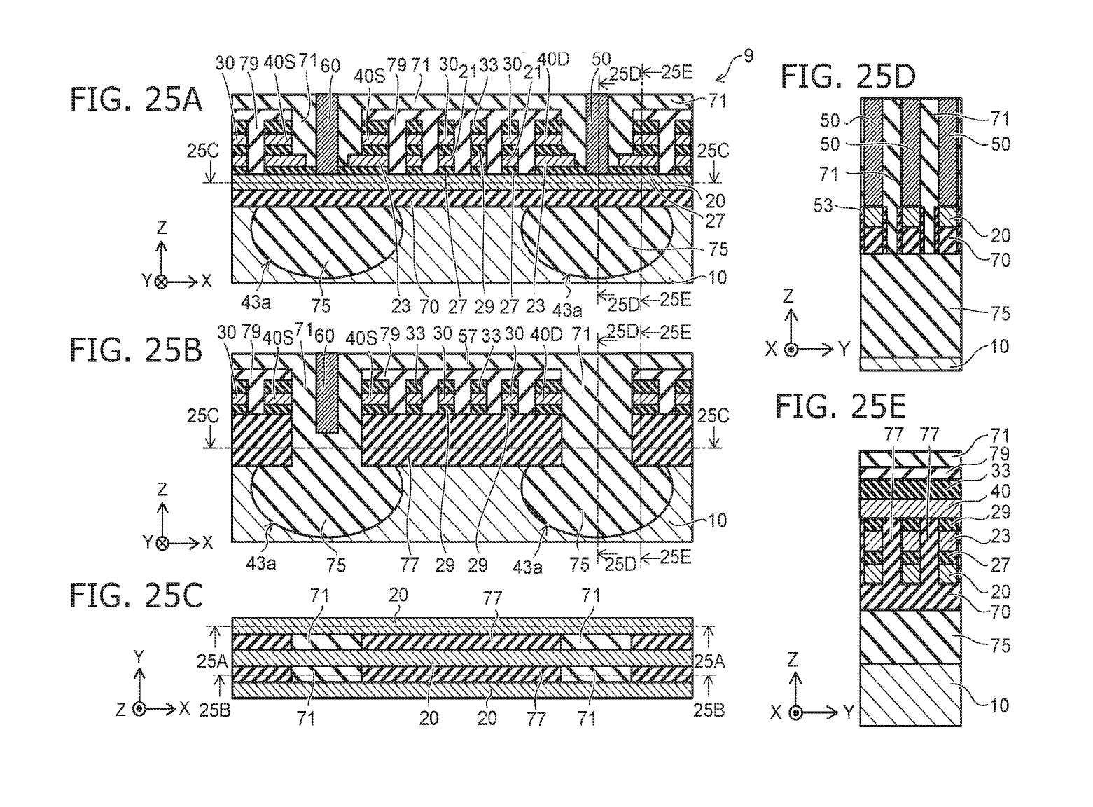

FIGS. 25A to 25E are schematic cross-sectional views showing a memory cell array 9 according to a variation of the third embodiment. In the memory cell array 9, for example, the insulating layer 75 has a cross section having an elliptical configuration. For example, such a configuration is obtained by expanding the hollows 43a further using CDE after the wet etching using KOH. In other words, by using CDE, the inner surfaces of the hollows 43a surrounded with the (111) surface of silicon can be changed to curved surfaces. Thereby, the hollows 43a can be made, which have the cross sections having elliptical configurations, for example.

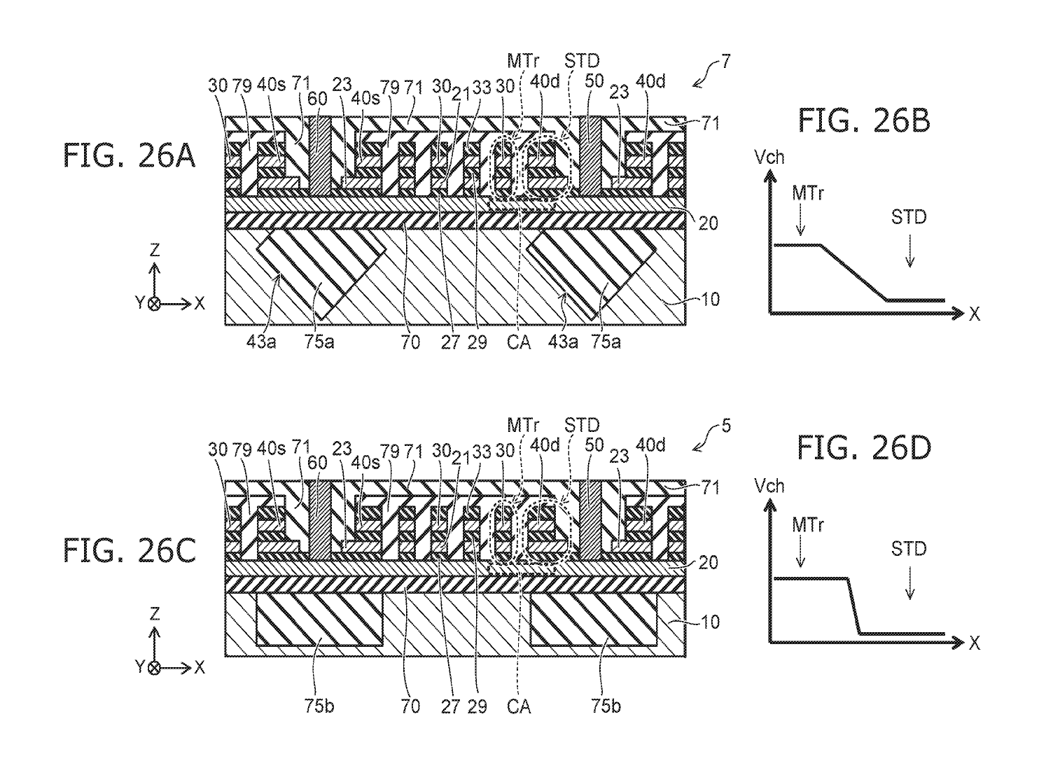

FIGS. 26A to 26D show the memory cell array 7 according to the embodiment and the memory cell array 5 according to the first embodiment. FIGS. 26B and 26D show the potential distribution of a region CA between the channel of the selection transistor STD and the channel of the memory cell transistor MTr adjacent to the selection transistor STD.

The memory cell array 7 shown in FIG. 26A includes an insulating layer 75b having a thickness in the Z-direction that increases gradually in the direction from the memory cell transistors MTr toward the selection transistor STD. On the other hand, in the memory cell array 5 shown in FIG. 26C, the thicknesses in the Z-direction of the insulating layers 70 and 75a between the substrate 10 and the semiconductor layers 20 changes in a step configuration in the direction from the memory cell transistors MTr toward the selection transistor STD.

Accordingly, the channel potential Vch changes gradually between the memory cell transistor MTr and the selection transistor STD in the memory cell array 7 as shown in FIG. 26B. On the other hand, the channel potential Vch changes abruptly between the memory cell transistor MTr and the selection transistor STD in the memory cell array 5 as shown in FIG. 26D.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device, comprising:
a conductive layer;
a semiconductor layer extending in a first direction on the conductive layer;
a first insulating layer provided between the conductive layer and the semiconductor layer;
a word line extending in a second direction on the semiconductor layer, the second direction intersecting the first direction;
a charge storage layer provided between the semiconductor layer and the word line; and
a circuit electrically connected to the conductive layer,
the circuit applying an electric potential to the conductive layer when programming data, the electric potential of the conductive layer having the same polarity as an electric potential of the word line.

2. The nonvolatile memory device according to claim 1, wherein the absolute value of the electric potential of the conductive layer is less than the absolute value of the electric potential of the word line.

3. The nonvolatile memory device according to claim 1, wherein the circuit applies the same electric potential as an electric potential of the semiconductor layer to the conductive layer when erasing the data.

4. The nonvolatile memory device according to claim 1, wherein the circuit includes a potential supply unit, a row decoder, and a sense amplifier, the potential supply unit being electrically connected to the conductive layer, the row decoder being electrically connected to the word line, the sense amplifier being electrically connected to the semiconductor layer.

5. The nonvolatile memory device according to claim 1, further comprising an interconnect electrically connected to the conductive layer and the semiconductor layer,
the circuit applying an electric potential to the conductive layer via the interconnect.

6. The nonvolatile memory device according to claim 5, further comprising a connecting portion extending through the insulating layer and electrically connecting the conductive layer to the semiconductor layer, wherein
the interconnect is electrically connected to the conductive layer via the connecting portion; and
the circuit applies an electric potential to the conductive layer via the connecting portion.

7. The nonvolatile memory device according to claim 1, further comprising a selection gate extending in the second direction on the semiconductor layer,
wherein the insulating layer has a first portion between the conductive layer and the word line, and a second portion between the conductive layer and the selection gate; and
a thickness of the first portion in a third direction being from the conductive layer toward the word line is thinner than a thickness of the second portion in the third direction.

8. The nonvolatile memory device according to claim 1, wherein the conductive layer is a semiconductor substrate.

9. The nonvolatile memory device according to claim 1, further comprising:
a selection gate extending in the second direction on the semiconductor layer; and
a second insulating layer provided in the conductive layer,
the semiconductor layer extending between the selection gate and the second insulating layer.

10. The nonvolatile memory device according to claim 9, wherein the second insulating layer has a thickness in a third direction that increases as separating from the charge storage layer in the first direction.

11. The nonvolatile memory device according to claim 9, wherein the second insulating layer includes a cavity positioned under the selection gate.

12. A nonvolatile memory device, comprising:
a first semiconductor layer extending in a first direction;
a first selection gate provided on the first semiconductor layer, the first selection gate extending in a second direction intersecting the first direction;
a second selection gate arranged with the first selection gate on the first semiconductor layer, the second selection gate extending in the second direction;
a first word line disposed between the first selection gate and the second selection gate, the first word line extending in the second direction;
a third selection gate provided on a side of the first semiconductor layer opposite to the first selection gate, the third selection gate extending in the second direction;
a fourth selection gate provided on a side of the first semiconductor layer opposite to the second selection gate, the fourth selection gate extending in the second direction;
a second word line provided on a side of the first semiconductor layer opposite to the first word line, the second word line extending in the second direction;
a second semiconductor layer extending in the first direction between the third selection gate and the first semiconductor layer, between the second word line and the first semiconductor layer, and between the fourth selection gate and the first semiconductor layer;
an insulating layer provided between the first semiconductor layer and the second semiconductor layer;
a first charge storage layer provided between the first semiconductor layer and the first word line;
a second charge storage layer provided between the second semiconductor layer and the second word line;
a first connecting portion extending through the insulating layer and electrically connecting the first semiconductor layer to the second semiconductor layer.

13. The nonvolatile memory device according to claim 12, further comprising:
a second connecting portion extending through the insulating layer and electrically connecting the first semiconductor layer to the second semiconductor layer, wherein
the first selection gate, the first charge storage layer, and the second selection gate face the first semiconductor layer between the first connecting portion and the second connecting portion; and
the third selection gate, the second charge storage layer, and the fourth selection gate face the second semiconductor layer between the first connecting portion and the second connecting portion.

14. The nonvolatile memory device according to claim 13, further comprising:
a first interconnect electrically connected to the first connecting portion; and
a second interconnect electrically connected to the second connecting portion.

15. The nonvolatile memory device according to claim 12, wherein the first word line and the second word line are electrically connected to each other.

16. The nonvolatile memory device according to claim 12, further comprising:
first conductive layers provided respectively between the first semiconductor layer and the first selection gate and between the first semiconductor layer and the second selection gate, the first conductive layers including the same material as a material of the first charge storage layer; and
second conductive layers provided respectively between the second semiconductor layer and the third selection gate and between the second semiconductor layer and the fourth selection gate, the second conductive layers including the same material as a material of the second charge storage layer.

17. The nonvolatile memory device according to claim 16, wherein
one of the first conductive layers is electrically connected to the first selection gate;
the other of the first conductive layers is electrically connected to the second selection gate;
one of the second conductive layers is electrically connected to the third selection gate; and
the other of the second conductive layers is electrically connected to the fourth selection gate.
